(19) United States
(12) Patent Application Publication
(10) Pub. No.: US 2026/0282202 A1
(43) Pub. Date: Sep. 17, 2026

(54) EXTREME ULTRAVIOLET LIGHT GENERATION APPARATUS AND ELECTRONIC DEVICE MANUFACTURING METHOD

(71) Applicant: Gigaphoton Inc., Tochigi (JP)

(72) Inventors: Aritsune HIROSE, Tochigi (JP); Yuichi NISHIMURA, Tochigi (JP); Shogo KITASAKA, Tochigi (JP)

(73) Assignee: Gigaphoton Inc., Tochigi (JP)

(21) Appl. No.: 19/530,415

(22) Filed: Feb. 5, 2026

(30) Foreign Application Priority Data
Mar. 14, 2025 (JP) 2025-041454

(51) Int. Cl. H05G 2/00; G01N 21/956; G03F 1/22; G03F 7/00; G03F 7/20

(52) U.S. Cl. CPC H05G 2/0027; G01N 21/956; G03F 1/22; G03F 7/2004; G03F 7/70033; G01N 2021/95676; G01N 2201/061

(57) ABSTRACT

An extreme ultraviolet light generation apparatus generating extreme ultraviolet light includes a vibration element driven by an electric signal and vibrating a target substance output from a nozzle, a timing sensor detecting a time interval variation of droplet passage, a processor controlling a duty value of the electric signal, and an output measurement instrument measuring a physical quantity for obtaining a parameter. The processor selects duty values with which the time interval variation acquired without generating the extreme ultraviolet light is less than a first threshold; specifies, as a first duty candidate, a duty value region in which the time interval variation is less than a second threshold and the parameter is less than a third threshold, both thereof being acquired for each selected duty value while generating the extreme ultraviolet light; and determines a duty value for vibrating the vibration element out of the first duty candidate.

### CROSS-REFERENCE TO RELATED APPLICATIONS

The present application claims the benefit of Japanese Patent Application No. 2025-041454, filed on Mar. 14, 2025, the entire contents of which are hereby incorporated by reference.

### BACKGROUND

### 1. Technical Field

The present disclosure relates to an extreme ultraviolet light generation apparatus and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system. As the EUV light generation apparatus, a laser produced plasma (LPP) type apparatus using plasma generated by irradiating a target substance with laser light has been developed.

### LIST OF DOCUMENTS

### Patent Documents

Patent Document 1: Japanese Patent Application Publication No. 2023-130282

### SUMMARY

An extreme ultraviolet light generation apparatus according to an aspect of the present disclosure is an extreme ultraviolet light generation apparatus configured to generate extreme ultraviolet light by irradiating a target substance with laser light. The extreme ultraviolet light generation apparatus includes a nozzle configured to output the target substance, a vibration element configured to be driven by an input of an electric signal of a rectangular wave and apply vibration to the target substance to be output from the nozzle to generate droplets of the target substance, a timing sensor configured to detect a time interval variation of passage of the droplets output from the nozzle, a processor configured to control a duty value of the electric signal for vibrating the vibration element, and an output measurement instrument configured to measure physical quantity for obtaining a parameter related to the generated extreme ultraviolet light. Here, the processor acquires the time interval variation as changing the duty value while generating the droplets without generating the extreme ultraviolet light; selects a plurality of duty values with which the time interval variation is less than a first threshold; acquires the time interval variation and the parameter for each of the plurality of selected duty values as changing the duty value in a duty value region including the corresponding duty value while generating the extreme ultraviolet light to specify, as a first duty candidate, the duty value region in which the time interval variation is less than a second threshold and the parameter is less than a third threshold; and determines a duty value for vibrating the vibration element out of the first duty candidate.

An electronic device manufacturing method according to an aspect of the present disclosure includes generating extreme ultraviolet light using an extreme ultraviolet light generation apparatus, outputting the extreme ultraviolet light to an exposure apparatus, and exposing a photosensitive substrate to the extreme ultraviolet light in the exposure apparatus to manufacture an electronic device. Here, the extreme ultraviolet light generation apparatus includes a nozzle configured to output a target substance, a vibration element configured to be driven by an input of an electric signal of a rectangular wave and apply vibration to the target substance to be output from the nozzle to generate droplets of the target substance, a timing sensor configured to detect a time interval variation of passage of the droplets output from the nozzle, a processor configured to control a duty value of the electric signal for vibrating the vibration element, and an output measurement instrument configured to measure a physical quantity for obtaining a parameter related to the extreme ultraviolet light generated by irradiating a target substance with laser light. The processor acquires the time interval variation as changing the duty value while generating the droplets without generating the extreme ultraviolet light; selects a plurality of duty values with which the time interval variation is less than a first threshold; acquires the time interval variation and the parameter for each of the plurality of selected duty values as changing the duty value in a duty value region including the corresponding duty value while generating the extreme ultraviolet light to specify, as a first duty candidate, the duty value region in which the time interval variation is less than a second threshold and the parameter third threshold; and determines a duty value for vibrating the vibration element out of the first duty candidate.

An electronic device manufacturing method according to an aspect of the present disclosure includes generating extreme ultraviolet light using an extreme ultraviolet light generation apparatus, inspecting a defect of a mask by irradiating the mask with the extreme ultraviolet light, selecting a mask using a result of the inspection, and exposing and transferring a pattern formed on the selected mask onto a photosensitive substrate. Here, the extreme ultraviolet light generation apparatus includes a nozzle configured to output a target substance, a vibration element configured to be driven by an input of an electric signal of a rectangular wave and apply vibration to the target substance to be output from the nozzle to generate droplets of the target substance, a timing sensor configured to detect a time interval variation of passage of the droplets output from the nozzle, a processor configured to control a duty value of the electric signal for vibrating the vibration element, and an output measurement instrument configured to measure a physical quantity for obtaining a parameter related to the extreme ultraviolet light generated by irradiating a target substance with laser light. The processor acquires the time interval variation as changing the duty value while generating the droplets without generating the extreme ultraviolet light; selects a plurality of duty values with which the time interval variation is less than a first threshold; acquires the time interval variation and the parameter for each of the plurality of selected duty values as changing the duty value in a duty value region including the corresponding duty value while generating the extreme ultraviolet light to specify, as a first duty candidate, the duty value region in which the time interval variation is less than a second threshold and the parameter is less than a third threshold; and determines a duty value for vibrating the vibration element out of the first duty candidate.

### BRIEF DESCRIPTION OF THE DRAWINGS

Embodiments of the present disclosure will be described below merely as examples with reference to the accompanying drawings.

FIG. 1 is a schematic diagram showing the configuration for measuring a droplet passage interval being a time interval of droplet passage.

FIG. 2 is a schematic diagram of an output signal (passage timing signal) of a light receiving element of a droplet detection sensor.

FIG. 3 is a diagram showing an example of an electric signal to be applied to a piezoelectric element for generating a droplet.

FIG. 4 is a diagram schematically showing a configuration example of an LPP EUV light generation system according to a comparative example.

FIG. 5 is a flowchart showing main flow of operation of an EUV light generation apparatus.

FIG. 6 is a flowchart showing an example of a subroutine of DL combining adjustment applied to step S3 in FIG. 5.

FIG. 7 is a graph showing an example of a DL passage interval σ measured in the DL combining adjustment.

FIG. 8 is a flowchart showing an example of a subroutine of DL combining control applied to step S4 in FIG. 5.

FIG. 9 is a graph for explaining a process of changing a Duty in a performance improving direction.

FIG. 10 is a graph showing an example of change in the DL passage interval σ and the Duty with respect to a control time in the DL combining control.

FIG. 11 is an explanatory diagram of a mechanism that generates horizontal-direction DL positional deviation.

FIG. 12 is a graph showing a CE of a pulse train in each of a pulse-order combining failure state and a normal state.

FIG. 13 is a graph showing an example of a CE measurement value, a CE difference, and a frequency distribution of the CE difference in a case that a DL combining failure is occurring.

FIG. 14 is a graph showing an example of the CE measurement value, the CE difference, and the frequency distribution of the CE difference in a case that DL combining is normal.

FIG. 15 is a flowchart showing operation when DL combining performance is deteriorated during continuous operation of the EUV light generation apparatus.

FIG. diagram schematically showing the 16 is a configuration of the EUV light generation apparatus according to a first embodiment.

FIG. 17 is a flowchart showing operation when the DL combining performance is deteriorated during continuous irradiation of the EUV light generation apparatus according to the first embodiment.

FIG. 18 is a flowchart showing an example of subroutine of the DL combining control during irradiation applied to step S45 in FIG. 17.

FIG. 19 is an example of a graph in which measurement values obtained by measuring the indices being the DL passage interval σ and the CE deterioration rate while performing laser irradiation near a certain Duty among a plurality of listed Duties are plotted.

FIG. 20 is a flowchart showing an example of a process of a subroutine applied to step S53 in FIG. 18.

FIG. 21 shows a measurement order, in the graph of FIG. 19, of index values measured in accordance with the flowchart of FIG. 20.

FIG. 22 is a flowchart showing an example of a process of a subroutine applied to step S54 in FIG. 18.

FIG. 23 is an explanatory diagram showing an example of selecting an optimum Duty from five candidates.

FIG. 24 is a flowchart showing an example of the subroutine of the DL combining control based on the index value.

FIG. 25 is a graph showing relationship between the Duty acquired in step S93 and the index value.

FIG. 26 is a graph for explaining a process of changing the Duty in the improving direction of the index.

FIG. 27 is an example of a graph in which the index obtained through a DL performance deterioration determination process during DL combining control are plotted.

FIG. 28 is a diagram schematically showing the configuration of an exposure apparatus connected to the EUV light generation apparatus according to the first embodiment.

FIG. 29 is a diagram schematically showing the configuration of an inspection apparatus connected to the EUV light generation apparatus according to the first embodiment.

### DESCRIPTION OF EMBODIMENTS

### Contents

1. Description of terms
   1.1 DL passage interval σ
   1.2 Duty
2. Outline of EUV light generation system according to comparative example
   2.1 Configuration
   2.2 Operation
      2.2.1 Example of DL combining adjustment
      2.2.2 Example of DL combining control
   2.3 Effect
   2.4 Problem
3. First Embodiment
   3.1 Configuration
   3.2 Operation
      3.2.1 Example of DL combining control based on EUV light
      3.2.2 DL performance deterioration determination method during DL combining control
   3.3 Effect
4. Electronic device manufacturing method
5. Processor
6. Others

Hereinafter, an embodiment of the present disclosure will be described in detail with reference to the drawings. The embodiment described below shows some examples of the present disclosure and do not limit the contents of the present disclosure. Also, all configurations and operation described in the embodiment are not necessarily essential as configurations and operation of the present disclosure. Here, the same components are denoted by the same reference numeral, and duplicate description thereof is omitted.

### 1. Description of Terms

### 1.1 DL Passage Interval σ

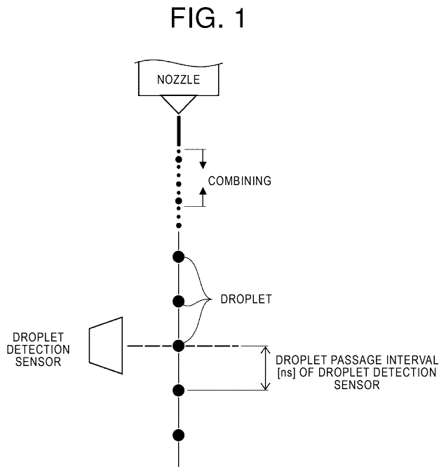

FIG. 1 is a schematic diagram showing the configuration for measuring a droplet passage interval being a time interval of droplet passage. FIG. 1 shows a nozzle that ejects a target substance, droplets formed by the target substances ejected from the nozzle, and a droplet detection sensor being a timing sensor that detects a timing at which the droplet passes. The droplet detection sensor is arranged facing a position through which the droplet passes. The droplet detection sensor includes a light receiving element (not shown), and detects a change in the output voltage of the light receiving element caused by passage of the droplet. A light emission trigger detection threshold for light emission trigger of a pulse laser device is set for the voltage of the light receiving element. The droplet detection sensor may include an illumination light source (not shown) for illuminating the droplet.

A “droplet” is a form of a target supplied into a chamber. The droplet may refer to a droplet-shaped target having a substantially spherical shape due to surface tension of a molten target substance. In the present specification and drawings, the expression “DL” is an abbreviation of a “droplet”.

The jet of the target substance ejected from the nozzle is separated into droplets, and a plurality of droplets is combined to form a DL. The normally-output DL obtained by combining a specified number of droplets creates a relatively large shadow. Therefore, when the normally-output DL passes beside the droplet detection sensor, the voltage of the light receiving element is greatly reduced. As a result, the voltage of the light receiving element falls below the light emission trigger detection threshold, causing a trigger start point of the pulse laser device.

On the other hand, depending on DL generation conditions, the DL having insufficient combining number and the droplet having no combining occur. Although the shadow due to the DL with combining failure is small and the voltage drop of the light receiving element is small, the voltage of the light receiving element may fall below the light emission trigger detection threshold to cause the trigger start point of the pulse laser device. When the DL with combining failure is irradiated with laser light, debris increases, which may cause deterioration of optical components.

In order to avoid such an event, the DL generation condition is determined using a detection interval (hereinafter, referred to as a “DL passage interval”) of a signal indicating the voltage of the light receiving element falling below the light emission trigger detection threshold as an index. Since the DL passage interval becomes a predetermined DL generation period when DL combining is normal, the DL combining is evaluated by an index of a DL passage interval variation σ calculated by the following Expression 1.

$$DL passage interval variation σ = \sqrt{\frac{1}{n} {\sum }_{i = 1}^{n} {( Ii - Iave )}^{2}} \qquad ( Expression 1 )$$

In Expression 1, n is the number of calculated samples, Ii is the i-th DL passage interval, and Iave is the average of the DL passage intervals for the number of calculation samples. Hereinafter, the DL passage interval variation σ is referred to as a “DL passage interval σ”. The unit of the DL passage interval σ is, for example, nanosecond [ns].

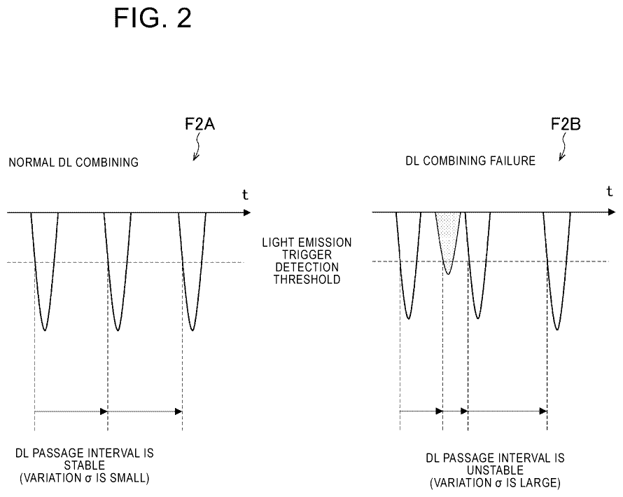

FIG. 2 is a schematic diagram of an output signal (passage timing signal) of the light receiving element of the droplet detection sensor. In FIG. 2, the horizontal axis represents time, and the vertical axis represents, for example, a voltage. FIG. F2A on the left side of FIG. 2 shows a case in which the DL passage interval is stable. Further, FIG. F2B on the right side of FIG. 2 shows a case in which the DL passage interval is unstable. When the DL combining is normal, the DL passage interval is stable and the DL passage interval σ is small, as shown in FIG. F2A on the left side. On the other hand, when the DL combining is defective, the DL passage interval becomes unstable and the DL passage interval σ is large, as shown in FIG. F2B on the right side.

### 1.2 Duty

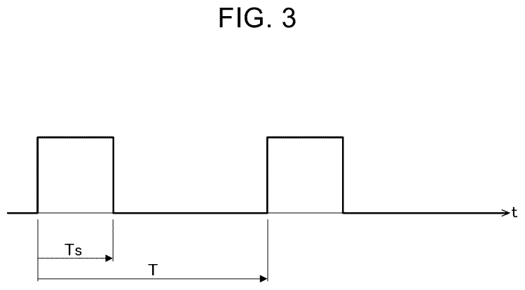

FIG. 3 is a diagram showing an example of an electric signal to be applied to a piezoelectric element for generating a droplet. FIG. 3 shows an example of rectangular wave having a predetermined cycle. In FIG. 3, the horizontal axis represents time, and the vertical axis represents the voltage. “Duty” is a ratio [%] of an on time (high potential voltage time) Ts in one rectangular wave cycle T.

### 2. Outline of EUV Light Generation System According to Comparative Example

### 2.1 Configuration

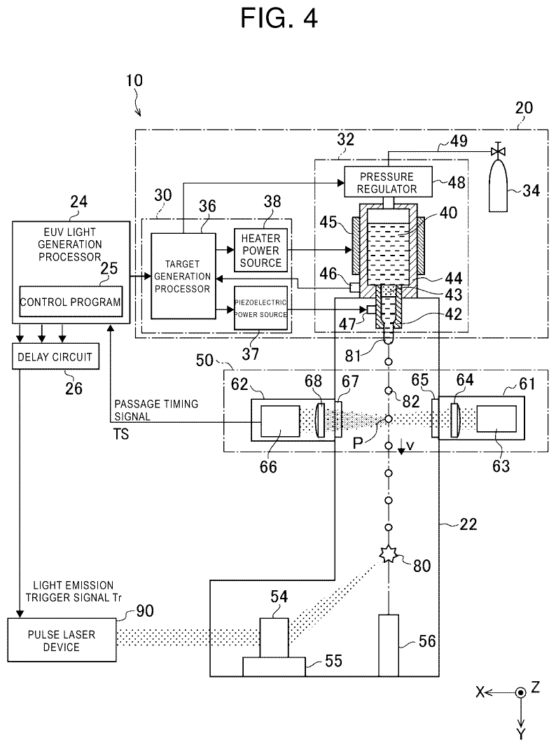

FIG. 4 is a diagram schematically showing a configuration example of an LPP EUV light generation system according to a comparative example. The comparative example of the present disclosure is an example recognized by the applicant as known only by the applicant, and is not a publicly known example admitted by the applicant. The expression “EUV light” is an abbreviation for “extreme ultraviolet light”.

An EUV light generation apparatus 10 includes a target generation system 20, a chamber 22, an EUV light generation processor 24, and a delay circuit 26. The EUV light generation apparatus 10 is used together with a pulse laser device 90. In the present disclosure, a system including the EUV light generation apparatus 10 and the pulse laser device 90 is referred to as the EUV light generation system.

The target generation system 20 includes a target control system 30, a target supply unit 32, and an inert gas supply unit 34. The target control system 30 includes a target generation processor 36, a piezoelectric power source 37, and a heater power source 38.

The target supply unit 32 includes a nozzle 42 having a hole for outputting a molten target substance 40, a filter 43, a tank 44 for storing the target substance 40, a heater 45, a temperature sensor 46, a piezoelectric element 47, and a pressure regulator 48.

The nozzle 42 corresponds to the nozzle shown in FIG. 1. The filter 43 is arranged upstream of the nozzle 42 and removes impurities contained in the target substance 40. The target substance 40 is, for example, tin (Sn). The nozzle 42, the heater 45, and the temperature sensor 46 are fixed to the tank 44. The piezoelectric element 47 is fixed to the nozzle 42.

The pressure regulator 48 is arranged at a pipe 49 between the inert gas supply unit 34 and the tank 44. An inert gas supplied from the inert gas supply unit 34 may be, for example, an Ar gas or an He gas.

The target substance 40 in the tank 44 is output as a jet 81 from the nozzle 42 owing to the pressure difference between the pressure of the inert gas supplied from the pressure regulator 48 and the pressure in the chamber 22. When vibration is applied to the nozzle 42 by the piezoelectric element 47, the jet 81 output from the nozzle 42 is separated into droplet forms to form a droplet 82 (hereinafter, referred to as the DL 82).

The chamber 22 includes a droplet position sensor 50 (hereinafter, referred to as the DL position sensor 50), a laser light concentrating optical system 54, a two-axis stage 55, and a target collection unit 56.

The DL position sensor 50 corresponds to the droplet detection sensor shown in FIG. 1. The DL position sensor 50 includes a light source unit 61 and a light receiving unit 62.

The light source unit 61 includes a CW laser 63 which is a light source, an illumination optical system 64 which is a light concentrating lens, and a window 65. The light source unit 61 is arranged so as to illuminate the DL 82 at a predetermined position P on a target trajectory between the nozzle 42 of the target supply unit 32 and a plasma generation region 80. The DL position sensor 50 is an example of the “timing sensor” in the present disclosure.

The light receiving unit 62 includes an optical sensor 66 which is a light receiving element, and a window 67 and a light receiving optical system 68 for introducing CW laser light to the optical sensor 66. The light receiving unit 62 is arranged so as to receive the CW laser light output from the light source unit 61. When the DL 82 blocks the CW laser light, the output of the optical sensor 66 decreases. That is, when the DL 82 passes through the position P, the light receiving unit 62 outputs a passage timing signal TS whose voltage drops. The passage timing signal TS is a signal indicating a timing at which the DL 82 has passed through the position P.

The passage timing signal TS output from the DL position sensor 50 is input to the delay circuit 26 via the EUV light generation processor 24. The EUV light generation processor 24 includes a control program 25. The EUV light generation processor 24 may be connected to the delay circuit 26 via a signal line for setting the delay time of the delay circuit 26. The delay circuit 26 may be configured separately from the EUV light generation processor 24 or may be configured as a part of the EUV light generation processor 24.

The delay circuit 26 adds the delay time to the passage timing signal TS to generate a light emission trigger signal Tr. The light emission trigger signal Tr output from the delay circuit 26 is input to the pulse laser device 90.

The pulse laser device 90 outputs pulse laser light based on the light emission trigger signal Tr. The pulse laser device 90 may be, for example, a CO₂ laser device. Further, the pulse laser device 90 may be a solid-state laser device in which a crystal obtained by doping any one of YVO₄ (yttrium-vanadium oxide), YLF (yttrium-lithium fluoride), and YAG (yttrium-aluminum-garnet) with an impurity is used as a laser medium.

The laser light concentrating optical system 54 is an optical system that concentrates the pulse laser light output from the laser device 90 and introduced into the chamber 22 on the plasma generation region 80. The laser light concentrating optical system 54 is supported by the two-axis stage 55. The two-axis stage 55 can move the laser light concentrating optical system 54 in two axis directions of a first axis direction and a second axis direction. For example, the first axis direction may be a Z-axis direction, and the second axis direction may be a Y-axis direction.

In the present specification, the direction in which the EUV light is output from the chamber 22 of the EUV light generation apparatus 10 toward an external apparatus such as an exposure apparatus (not shown) is defined as the Z-axis direction. An X-axis direction and the Y-axis direction are orthogonal to the Z-axis direction and orthogonal to each other, and the target travel direction in which the DL 82 output from the nozzle 42 travels toward the plasma generation region 80, that is, the direction of the trajectory of the DL 82 is defined as the Y-axis direction. In the subsequent drawings, the same coordinate system as that introduced in FIG. 4 is used.

By adjusting the position of the laser light concentrating optical system 54 by the two-axis stage 55, it is possible to adjust the concentration position of the pulse laser light into the plasma generation region 80. The laser light concentrating optical system 54 may include a plurality of optical elements.

The target collection unit 56 is arranged on the trajectory of the DL 82, and collects the DL 82 which has not been irradiated with the pulse laser light.

Further, an EUV light concentrating mirror (not shown) is arranged in the chamber 22. The EUV light concentrating mirror has a spheroidal reflection surface. A multilayer reflection film in which molybdenum and silicon are alternately laminated is formed on the reflection surface of the EUV light concentrating mirror. The EUV light concentrating mirror has a first focal point and a second focal point and is positioned such that the first focal point is located in the plasma generation region 80. The EUV light concentrating mirror selectively reflects EUV light from among the radiation light that is radiated from plasma generated at the plasma generation region 80. The EUV light concentrating mirror concentrates the selectively reflected EUV light on the second focal point (intermediate focal point). An aperture (not shown) is arranged at the intermediate focal point, and the EUV light having passed through the aperture enters the external apparatus.

### 2.2 Operation

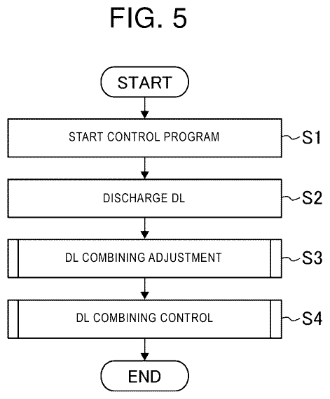

FIG. 5 is a flowchart showing main flow of operation of the EUV light generation apparatus 10.

In step S1, the EUV light generation processor 24 executes the control program 25 when EUV light generation command is ordered from an operator or an external apparatus (not shown). When the EUV light generation processor 24 starts executing the control program 25, the DL 82 is discharged from the target supply unit 32 in step S2. The EUV light generation processor 24 and the target generation processor 36 are separate from each other, but may be configured as a single processor. In that case, operation of the target generation processor 36 may be performed by the EUV light generation processor 24.

In step S2, the target generation processor 36 controls the heater power source 38 based on a detection value of the temperature sensor 46 so that the temperature of Sn in the target supply unit 32 becomes equal to or higher than the melting point and to melt Sn stored in the tank 44. For example, the target generation processor 36 controls the heater power source 38 so that Sn in the target supply unit 32 becomes a predetermined temperature of 232° C. to 300° C. The target generation processor 36 also controls the inert gas to a predetermined pressure by the pressure regulator 48, for example, the pressure of 0.2 MPa to 40 MPa, to output the liquid Sn inside the tank 44 to the outside of the nozzle 42.

In step S3, the target generation processor 36 performs processing of DL combining adjustment. The DL combining adjustment is the processing of adjusting into an appropriate Duty using the DL passage interval σ as an index. The target generation processor 36 vibrates the nozzle 42 so that the jet 81 of the liquid Sn output from the nozzle 42 is turned into droplets and a plurality of droplets are combined to generate a combined DL having a predetermined diameter at a predetermined cycle. For example, the EUV light generation processor 24 applies an electric signal of a rectangular wave having a predetermined frequency and a predetermined Duty to the piezoelectric element 47 via the piezoelectric power source 37, and causes the nozzle 42 to vibrate at a predetermined frequency. The piezoelectric element 47 is an example of a vibration element that applies vibration to the liquid target substance 40.

Hereinafter, the term “DL” in the case of generating a DL or generation of a DL in the present specification refers to a combined DL unless otherwise specified. In the present specification, the Duty of the voltage waveform of the rectangular wave applied to the piezoelectric element 47 is referred to as “Duty for the piezoelectric element 47”, “piezoelectric Duty”, or simply “Duty”. The Duty is one of vibration parameters related to the vibration of the piezoelectric element 47, and the value of the Duty is referred to as a “Duty value”.

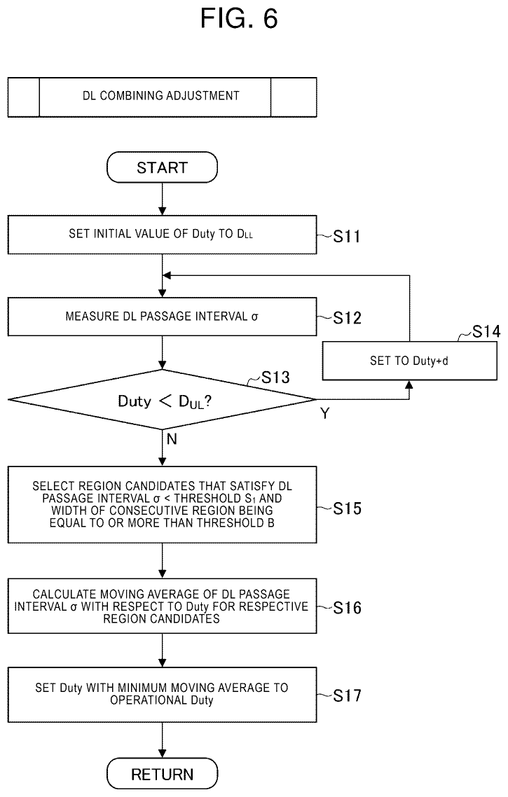

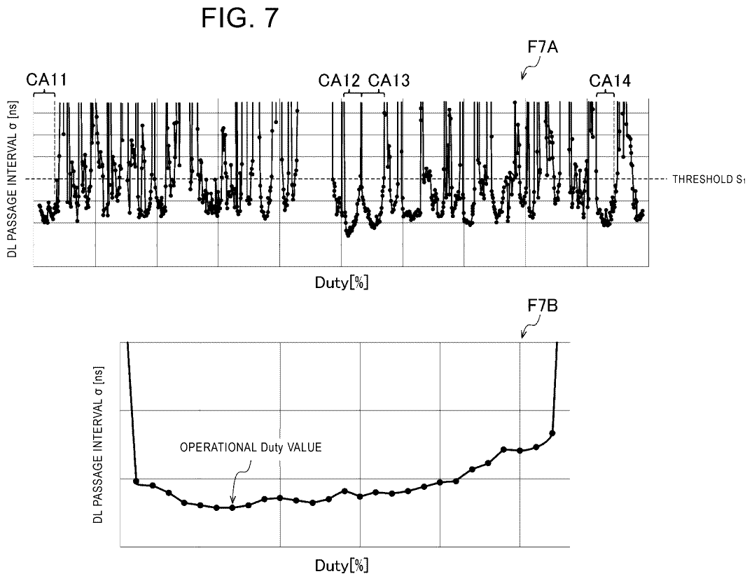

At this time, the target generation processor 36 measures the DL passage interval σ with respect to the Duty and stores the DL passage interval σ in association with the Duty. Then, the piezoelectric element 47 is driven by the rectangular wave of the Duty with which the DL passage interval σ is less than a threshold. A specific example of a subroutine of the DL combining adjustment applied to step S3 will be described later with reference to FIGS. 6 and 7.

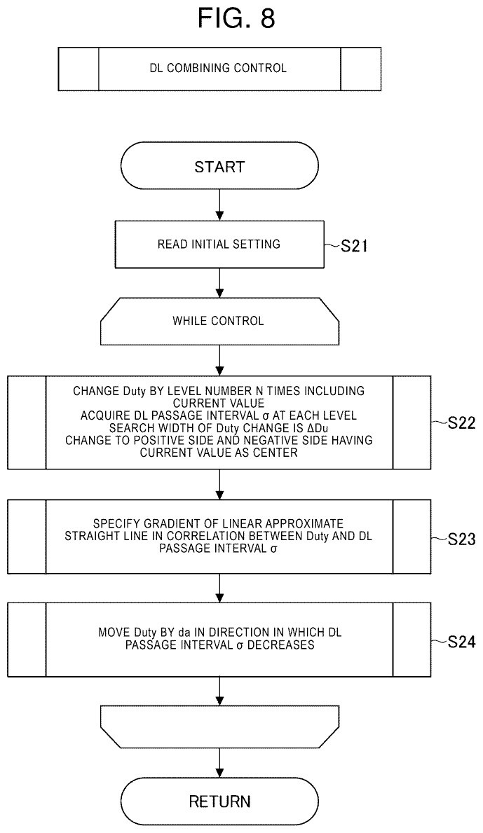

Thereafter, in step S4, target the generation processor 36 starts DL combining control of maintaining a DL combining state by finely adjusting the Duty for the piezoelectric element 47 using the DL passage interval σ as an index. Here, the DL combining control may be performed irrespective of non-irradiation (at the time of EUV non-emission) and irradiation (at the time of EUV emission) to the DL 82 with the pulse laser light. A specific example of a subroutine applied to the DL combining control in step S4 will be described later with reference to FIG. 8.

After step S4 is completed, the EUV light generation processor 24 ends the flowchart of FIG. 5.

### 2.2.1 Example of DL Combining Adjustment

FIG. 6 is a flowchart showing an example of the subroutine of the DL combining adjustment applied to step S3 in FIG. 5. The present subroutine is executed during DL discharging at the time of EUV non-emission.

When the process in step S3 is started, in step S11, the target generation processor 36 reads initial parameters and sets the Duty for the piezoelectric element 47 to a lower limit value D_{LL} which is an initial value. In addition to the lower limit value D_{LL}, the initial parameters include an upper limit value D_{UL}, a step amount d, a number of calculation samples of the DL passage interval σ, a moving average number No of the DL passage interval σ, a threshold S₁ of the DL passage interval σ, and a threshold B of consecutive Duty width determination. Here, the threshold S₁ of the DL passage interval σ is an example of the “first threshold” in the present disclosure.

As typical values of the initial parameters, the lower limit value D_{LL} may be 1%, the upper limit value D_{UL} may be 99%, the step amount d may be 0.1%, the number of calculation samples of the DL passage interval σ may be 10000, the moving average number No of the DL passage interval σ may be 0.6%, and the threshold S₁ of the DL passage interval σ may be 170 ns. When the step amount d is 0.1%, the moving average number No of the DL passage interval σ being 0.6% means that the number of sections of the moving average is 0.6÷0.1=6. Further, the threshold B of the consecutive Duty width determination may be set by determining a value, by experiment or the like, with which DL combining performance can be maintained for a long period of time. The threshold B of the consecutive Duty width determination may be 0.6% or more and, for example, the threshold B may be 0.6%.

The target generation processor 36 can change the Duty in units of the step amount d in a numerical range from the lower limit value D_{LL} to the upper limit value D_{UL}.

In step S12, the target generation processor 36 measures the DL passage interval σ with each Duty value. That is, the target generation processor 36 controls the piezoelectric power source 37 so as to apply the electric signal of the rectangular wave having the set Duty value to the piezoelectric element 47, and drives the piezoelectric element 47 via the piezoelectric power source 37 to generate the DL 82. Further, the target generation processor 36 acquires the passage timing signal TS via the EUV light generation processor 24, and calculates the DL passage interval σ based on the passage timing signal and Expression 1. Then, the target generation processor 36 stores the Duty and the DL passage interval σ in association with each other in a memory.

In step S13, the target generation processor 36 determines whether or not the set Duty value is smaller than the upper limit value D_{UL}. When the determination result of step S13 is Yes, the target generation processor 36 proceeds to step S14, sets a new Duty value by adding the step amount d to the set Duty value, and then returns to step S12.

The loop of steps S12 to S14 is repeated until the Duty value reaches the upper limit value D_{UL}. Thus, by measuring the DL passage interval σ with each Duty value while increasing the Duty from the lower limit value D_{LL} to the upper limit value Dur in increments of the step amount d, characteristic data (see FIG. 7) indicating the relationship between the Duty and the DL passage interval σ can be obtained.

When the Duty value reaches the upper limit value D_{UL} and the determination result of step S13 is No, the target generation processor 36 proceeds to step S15. In step S15, the target generation processor 36 selects region candidates that satisfy the condition that the DL passage interval σ is less than the threshold S₁ and that the size (width) of the region (consecutive region) of the consecutive Duty is equal to or more than the threshold B.

In step S16, the target generation processor 36 calculates the moving averages of the DL passage interval σ with respect to the Duty for the respective region candidates selected in step S15. In place of the moving average, the target generation processor 36 may perform a filter operation on the data sequence to smooth out protruding data.

In step S17, the target generation processor 36 sets the Duty value with which the moving average calculated in step S16 is the minimum to the operational Duty value. After step S17, the target generation processor 36 returns to the flowchart of FIG. 5.

FIG. 7 is a graph showing an example of the DL passage interval σ measured in the DL combining adjustment. In FIG. 7, the horizontal axis represents the Duty, and the vertical axis represents the DL passage interval σ. FIG. F7A at the upper stage of FIG. 7 shows an example of the DL passage interval σ obtained by scanning with the Duty value being from 1% to 99% in increments of 0.1% while the irradiation of the pulse laser light is stopped.

In FIG. F7A at the upper stage, four region candidates CA11, CA12, CA13, CA14 are regions satisfying the condition that the DL passage interval σ is less than the threshold S₁ and the width of the consecutive region is equal to or more than the threshold B of the consecutive Duty width determination. The region candidates CA11, CA12, CA13, CA14 are regions in the vicinity of the Duty values of 3%, 53%, 56%, and 93%, respectively.

Here, the moving average of the DL passage interval σ with the Duty is calculated for each of the four region candidates CA11, CA12, CA13, CA14, and the operational Duty value is set to the Duty value with which the moving average is the minimum. FIG. F7B at the lower stage of FIG. 7 is an enlarged graph of the region candidate CA12, and shows an example of the operational Duty value set from the moving averages.

### 2.2.2 Example of DL Combining Control

FIG. 8 is a flowchart showing an example of a subroutine of DL combining control applied to step S4 in FIG. 5. In the subroutine of the DL combining control of FIG. 8, the Duty is controlled using the DL passage interval σ as an index. The present subroutine can be performed at both the time of EUV non-light emission and the time of EUV light emission.

When the process of step S4 is started, in step S21, the target generation processor 36 reads initial settings. The parameters for performing the initial setting include a search range ΔDu of the Duty value, a search level number N of the Duty, a Duty moving amount da, and a number of calculation samples Ns of the DL passage interval σ. The target generation processor 36 reads the initial setting values for each of these parameters. For example, as the typical values of the parameters, the search width ΔDu may be 0.02%, the search level number N may preferably be 2 or more, for example, 5, the Duty moving amount da may be 0.02%, and the number of calculation samples of the DL passage interval σ may be 10000.

In step S22, the target generation processor 36 changes the Duty by the search level number N times including the current value, based on the initial settings read in step S21, and acquires the DL passage interval σ at each level. The interval between the search level numbers N may be the search width ΔDu, and the order of the Duty value to be set at the time of the level change may be arbitrary. In addition, it is desirable that the range to be searched for by the search width ΔDu is set to a range in which a significant difference in DL combining performance is obtained.

The target generation processor 36 drives the piezoelectric element 47 with the respective Duty values of the N levels including the current value of the Duty to generate the DL 82. The target generation processor 36 acquires the DL passage interval σ for the generated DL 82 and obtains a correlation between the Duty and the DL passage interval σ.

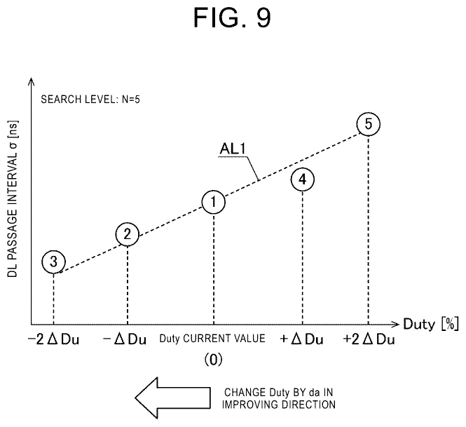

In step S23, the target generation processor 36 calculates a linear approximate straight line with the Duty as the horizontal axis and the DL passage interval σ as the vertical axis in the correlation between the Duty and the DL passage interval σ acquired in step S22, and specifies the gradient thereof (see FIG. 9).

In step S24, the target generation processor 36 changes the Duty in a performance improving direction, that is, in the direction in which the DL passage interval σ decreases, based on the gradient of the approximate straight line specified in step S23. For example, when the gradient is positive, the target generation processor 36 changes the Duty from the current value (0 position) to the negative direction. Further, when the gradient is negative, the target generation processor 36 changes the Duty from the current value to the positive direction. The change amount of the Duty at this time may be set to a Duty value that differs from the current value by the moving amount d, or any Duty value that is in the performance improving direction. The change amount in the Duty may be different depending on the value of the gradient. Thereafter, the piezoelectric element 47 is driven with the Duty value having the smaller DL passage interval σ.

Here, when the absolute value of the gradient can be regarded as 0, the target generation processor 36 may not change the Duty.

After step S24, the target generation processor 36 returns to step S22 and repeats the same processes (steps S22 to S24) using the changed Duty as the current value.

The processes of steps S22 to S24 are for maintaining the DL combining state by finely adjusting the Duty value using the DL passage interval σ as an index, and are performed repeatedly as long as the combining state of the DL needs to be maintained. When there is no need to maintain the DL combining state in association with the stop of DL outputting by a stop command or the like from an operator or an external apparatus (not shown), the EUV light generation processor 24 ends the repetitive processes and ends the present subroutine.

FIG. 9 is a graph for explaining the process of changing the Duty in the performance improving direction. In FIG. 9, the horizontal axis represents the Duty, and the vertical axis represents the DL passage interval σ. Each circle in FIG. 9 represents a plot position of the DL passage interval σ with respect to the Duty, and a number in the circle represents a search order. In the example shown in FIG. 9, the Duty values of the search orders 1, 2, 3, 4, and 5 are “current value”, “current value−ΔDu”, “current value−ΔDu×2”, “current value+ΔDu”, and “current value+ΔDu×2”, respectively. From these five plot points, an approximate straight line AL1 indicated by a broken line in FIG. 9 can be obtained by linear approximation.

In the example of FIG. 9, a gradient of the approximate straight line AL1 has a positive value, and the direction in which the Duty is decreased with respect to the current value is the direction in which the value of the DL passage distance σ is improved. Therefore, in this case, as the process of step S24, the Duty value is changed from the current value to the negative direction by the moving amount da.

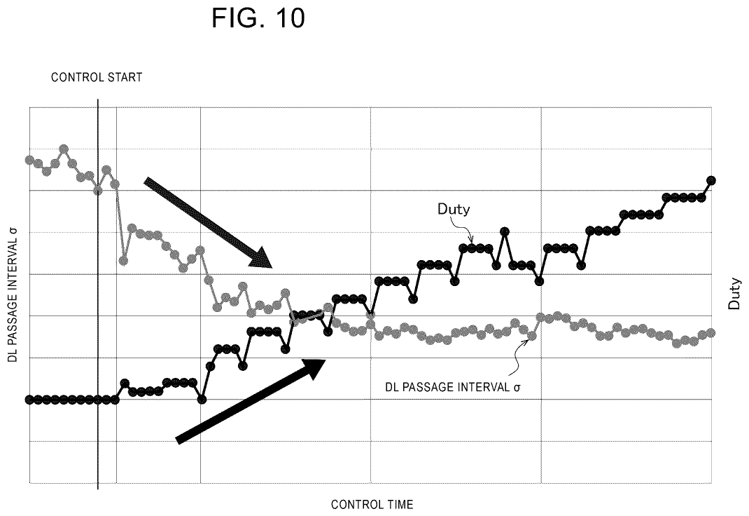

FIG. 10 is a graph showing an example of change in the DL passage interval σ and the Duty with respect to the control time in the DL combining control. In this example, the DL passage interval σ is improved by being controlled so as to increase the Duty value in a broad sense.

### 2.3 Effect

According to the EUV light generation apparatus 10 of the comparative example, since variation of the DL passage interval σ can be kept small, the EUV energy stability can be maintained satisfactorily. Further, since the Duty value with which the moving average has the minimum value is further selected from the excellent Duty region in the process of the DL combining adjustment (step S3), even if there is some disturbance, the DL passage interval σ does not deteriorate significantly, and the Duty once set can be maintained for a relatively long period of time.

### 2.4 Problem

When the DL combining performance is deteriorated during continuous operation of the EUV light generation apparatus 10 according to the comparative example, the DL combining adjustment described in step S3 is performed. At this time, to avoid generation of tin debris due to laser radiation to an abnormally-combined DL, the laser radiation is stopped during the operation of the DL combining adjustment. Even when a piezoelectric Duty with an excellent DL passage interval σ is selected by performing the DL combining control while the laser light is not radiated as described above, there has been a case in which the energy stability of the generated EUV light is poor.

The inventors have confirmed a phenomenon of a pulse-order combining failure that can cause such a problem. The pulse-order combining failure is a DL combining failure that occurs not continuously but intermittently, that is, in a pulse order manner, and is a combining failure in which DL positional deviation in a direction perpendicular to the DL travel direction occurs. When the DL travel direction is the vertical direction (longitudinal direction), the direction perpendicular to the DL travel direction is the horizontal direction (lateral direction). Hereinafter, the DL positional deviation in the direction perpendicular to the DL travel direction may be referred to as “horizontal-direction DL positional deviation”.

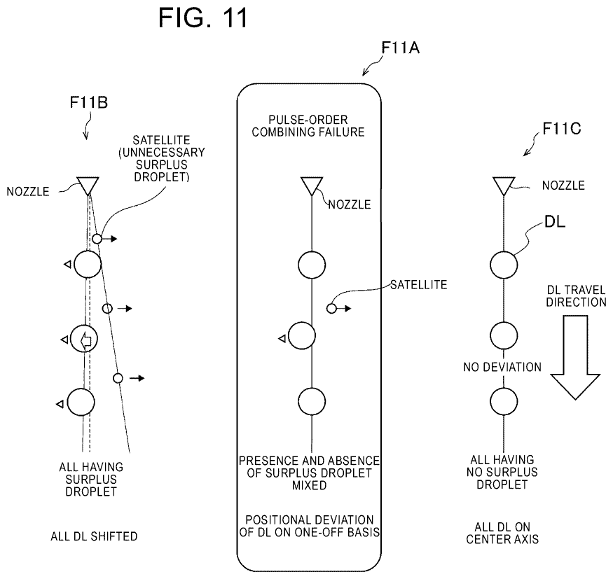

FIG. 11 is an explanatory diagram of a mechanism that generates horizontal-direction DL positional deviation. F11A on the center of FIG. 11 shows a state of the pulse-order combining failure. F11B on the left side of FIG. 11 shows a state in which horizontal-direction DL positional deviation is occurring with all the DLs continuously discharged from the nozzle 42. F11C on the right side of FIG. 11 shows a state in which no horizontal-direction DL positional deviation is occurring, and all the DLs continuously discharged from the nozzle 42 travels on the center axis of the nozzle 42. The DL trajectory when the DL discharged from the nozzle 42 is in a normal DL combining state coincides with the center axis of the nozzle 42.

As shown in F11B on the left side and F11C on the center, when an uncombined fine droplet (surplus droplet) is generated for the DL discharged from the nozzle 42, horizontal-direction DL positional deviation occurs with respect to the main DL (main droplet). Such an unnecessary surplus droplet is also called a “satellite”. When a surplus droplet is generated, a horizontal motion component of the surplus droplet is removed from the main DL due to the principle of momentum conservation, so that an opposite horizontal motion is given to the main DL, and it is considered that deviation occurs from the DL trajectory with no surplus droplet.

In the pulse-order combining failure, such surplus droplets are sporadically generated in a part of the plurality of DLs discharged from the nozzle 42, and the presence and absence of surplus droplets are mixed in the discharged DLs, so that horizontal-direction DL positional deviation occurs on a one-off basis.

Since the DL passage interval σ is an index of DL positional deviation in the DL travel direction, the pulse-order combining failure cannot be determined by the DL passage interval σ. The inventors have experimentally found that the pulse-order combining failure can be determined by a decrease in a conversion efficiency (CE) during EUV light generation.

The CE is the conversion efficiency of the EUV energy with respect to a driver laser energy and is calculated by the following expression.

$$CE = ( EUV energy / driver laser energy ) \times 100 ( \% ) \qquad ( Expression 2 )$$

The driver laser energy is the energy of the laser light radiated to the target substance 40. The CE is an example of the “energy conversion efficiency which is a ratio of the energy of the extreme ultraviolet light with respect to the energy of the laser light”.

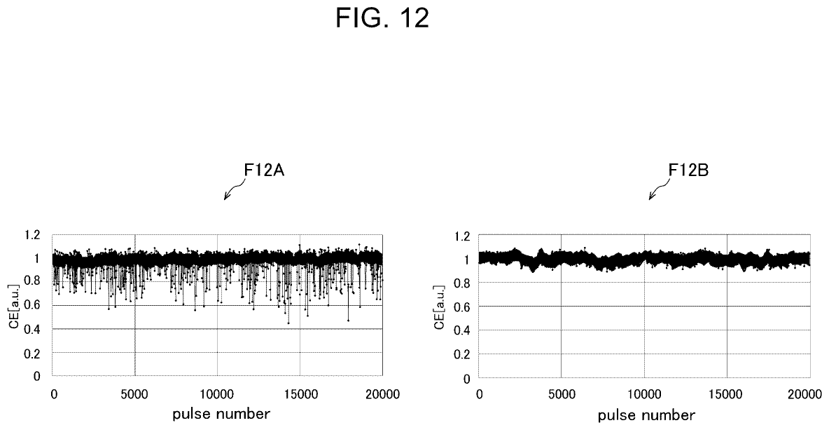

FIG. 12 is a graph showing the CE of a pulse train in each of a pulse-order combining failure state and a normal state. F12A on the left side of FIG. 12 shows the CE of the pulse train in the pulse-order combining failure state, and F12B on the right side shows the CE of the pulse train in the normal state. The horizontal axis represents the pulse number, and the vertical axis represents the CE in arbitrary units.

Due to the pulse-order combining failure, horizontal-direction DL positional deviation occurs intermittently, and when the deviated DL is irradiated with the laser light, a CE decrease occurs intermittently (in a pulse-order manner).

A CE deterioration rate can be used as one of indices for evaluating the CE decrease in a pulse-order manner. The CE deterioration rate is an index for confirming the frequency of the CE decrease due to the pulse-order combining failure.

The CE deterioration rate is calculated by the following steps.
Step 1: Record a CE measurement value for each pulse.
Step 2: Obtain a CE difference for each pulse.

Here, the CE difference is a difference in the CE between two consecutive pulses, and the CE difference dCE(k) is defined by the difference between CE(k−1) of the previous pulse and CE(k) of the current pulse where k is an integer representing the pulse number, as follows.

$$d C E ( k ) = C E ( k ) - CE ( k - 1 )$$

Step 3: Obtain a histogram of the CE difference.
Step 4: In the histogram of the CE difference, the number of events (pulses) distributed outside a normal range is counted, and the ratio thereof with respect to the population of the histogram is determined to obtain the CE deterioration rate.

In this case, the normal range may be a range in which the absolute value of the CE difference is, for example, less than 0.2.

When the CE deterioration rate is expressed as a percentage, it is defined as follows.

$$CE deterioration rate = \{ ( number of events in which CE difference is distributed \\ outside allowable range ) / number of samples n \} \times 100 ( \% )$$

The number of samples n may be, for example, 20000 pulses.

Here, the CE deterioration rate may be defined as a percentage of the value obtained by dividing the number of events in which the CE measurement value is distributed outside the allowable range by the number of samples n, instead of the definition of the above expression, but there is an advantage that a difference in the value is more likely to occur when the CE difference is used.

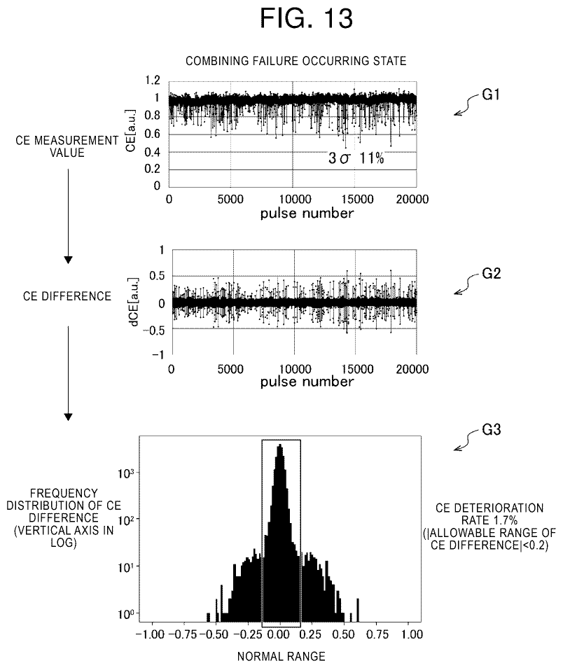

FIG. 13 is a graph showing an example of the CE measurement value, the CE difference, and a frequency distribution of the CE difference in a case that the DL combining failure is occurring. In a graph G1 shown in the upper stage of FIG. 13, the horizontal axis represents the pulse number and the vertical axis represents the CE measurement value in an arbitrary unit. In a graph G2 shown in the middle stage of FIG. 13, the horizontal axis represents the pulse number and the vertical axis represents the CE difference in an arbitrary unit. A graph G3 shown in the lower stage of FIG. 13 is a frequency distribution (histogram) of the CE difference. The vertical axis of the graph G3 is expressed in logarithmic (LOG) representation.

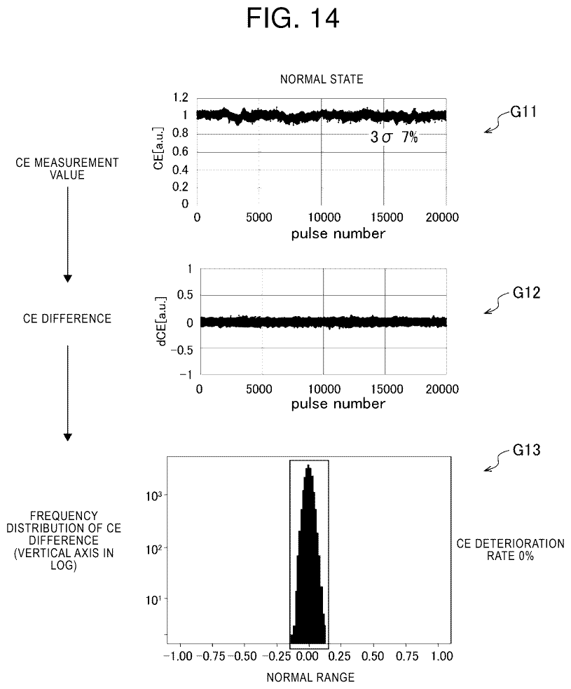

Further, FIG. 14 is a graph showing an example of the CE measurement value, the CE difference, and the frequency distribution of the CE difference in a case that the DL combining is normal. A graph G11 shown in the upper stage of FIG. 14 shows the CE measurement value, a graph G12 shown in the middle stage shows the CE difference, and a graph G13 shown in the lower stage shows the frequency distribution of the CE difference. The horizontal axis and the vertical axis of each graph are similar to those of the corresponding graph in FIG. 13.

As is apparent from a comparison between FIGS. 13 and 14, when a combining failure occurs, variations in the CE measurement value and the CE difference measured in pulse order are larger than those in the normal state. In the example of FIG. 14, 3σ of the CE measurement value in the normal state is 7%. On the other hand, in the example of FIG. 13, 3σ of the CE measurement value at the time of occurrence of the combining failure is 11%. Here, “σ” in “3σ” represents a standard deviation.

As shown in the lower stages of FIGS. 13 and 14, for example, when a range in which the absolute value of the CE difference is less than 0.2 (−0.2<dCE<−0.2) is set as the allowable range (normal range) of the CE difference, the CE deterioration rate at the normal time shown in the example of FIG. 14 is 0%, whereas the CE deterioration rate at the time of occurrence of the combining failure shown in the example of FIG. 13 is 1.7%.

Thus, by controlling the Duty of the piezoelectric element 47 using an index for evaluating the variation of the CE, such as the CE deterioration rate reflecting the DL combining state, it is possible to suppress the occurrence of the DL combining failure state which is difficult to detect by the DL passage interval σ. Instead of the CE deterioration rate, the Duty can be controlled by using an index such as 3σ of the CE measurement value and 3σ of the CE difference.

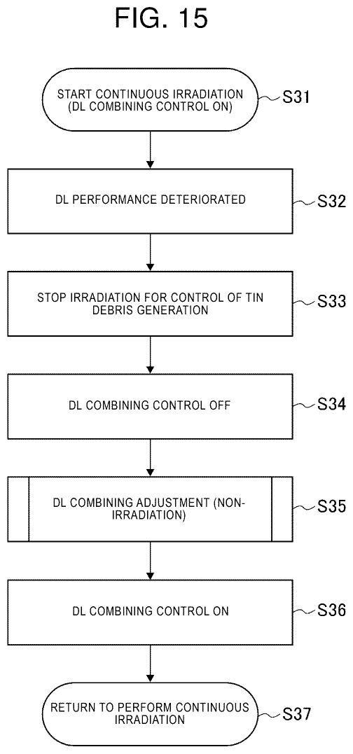

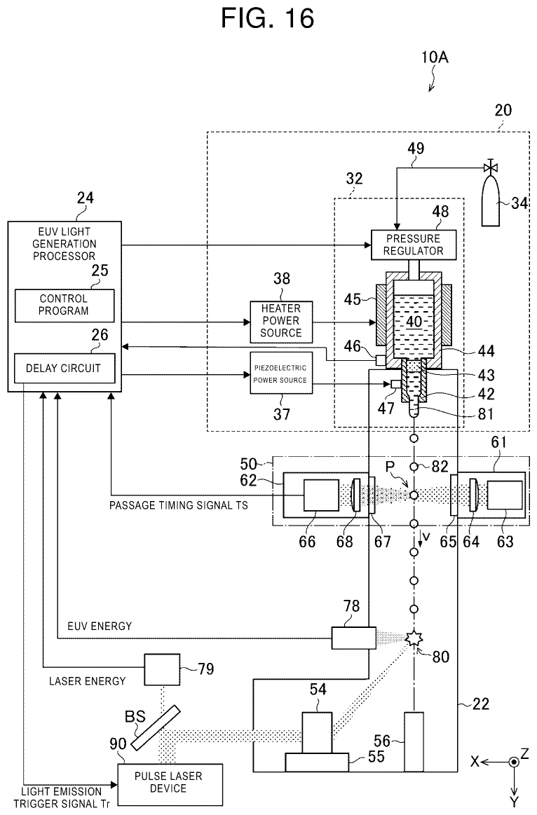

FIG. 15 is a flowchart showing the operation when the DL combining performance is deteriorated during the continuous operation of the EUV light generation apparatus 10.

In step S31, the EUV light generation processor 24 starts continuous irradiation of the DL with the laser light. Here, the “continuous irradiation” means that the DLs 82 are continuously generated by the target supply unit 32, and each DL 82 is irradiated with the laser light. A plurality of pulses of the laser light may be radiated to one DL 82, and the target substance 40 irradiated with the laser light is not limited to be in a state of the DL 82, and may be a diffused target in a state in which the target substance 40 is diffused obtained through the irradiation of the DL 82 with the laser light. In the present specification, the irradiation of the target substance 40 with the laser light may be referred to as “laser irradiation” or simply “irradiation”.

Step S31 is started by starting the DL combining control shown in step S4 in FIG. 5. The DL combining control (FIG. 8) is performed during the continuous irradiation.

Thereafter, when the DL performance deteriorates and the Duty becomes difficult to be set by the DL combining control (FIG. 8) during the continuous irradiation (step S32), the DL combining adjustment (FIG. 6) is to be performed. At this time, to avoid generation of tin debris due to the laser irradiation of the abnormally-combined DL (combining-failed DL), the EUV light generation processor 24 stops the laser irradiation in step S33.

Then, in step S34, the EUV light generation processor 24 stops the DL combining control. In this way, in step S35, the EUV light generation processor 24 performs the DL combining adjustment (FIG. 6) in a laser non-irradiation state.

After the piezoelectric Duty is set through the DL combining adjustment, in step S36, the EUV light generation processor 24 restarts the DL combining control. Thereafter, in step S37, the EUV light generation processor 24 returns to perform the continuous irradiation. After step S37, the operation of the EUV light generation apparatus 10 returns to step S31.

As described above, when the DL combining performance is deteriorated during the continuous operation, the laser irradiation is stopped (step S33), and the DL combining adjustment is performed (step S35). The EUV light generation processor 24 selects, through the DL combining adjustment, a piezoelectric Duty with an excellent DL passage interval σ, but the pulse-order combining failure cannot be determined by the DL passage interval σ.

That is, it has been found that, since the DL combining adjustment without laser irradiation is performed in step S35, the CE deterioration rate cannot be measured, and the piezoelectric Duty causing the pulse-order combining failure in the DL combining adjustment (causing a high CE deterioration rate) is selected in some cases.

Therefore, there is a need for an EUV light generation apparatus capable of performing Duty adjustment that satisfies both conditions of the DL passage interval σ and the CE deterioration rate.

### 3. First Embodiment

### 3.1 Configuration

FIG. 16 schematically shows the configuration of an EUV light generation apparatus 10A according to a first embodiment. The configuration shown in FIG. 16 will be described in terms of differences from the configuration of the EUV light generation apparatus 10 shown in FIG. 4.

The EUV light generation apparatus 10A includes an EUV energy sensor 78, a beam splitter BS, and a laser energy sensor 79. The EUV energy sensor 78 is arranged at a position where the plasma generation region 80 can be observed, and measures the EUV energy and transmits it to the EUV light generation processor 24. The EUV light generation processor 24 has a function as the target generation processor 36. The EUV energy sensor 78 is an example of the “EUV light detection sensor” in the present disclosure. The EUV energy sensor 78 and the laser energy sensor 79 are examples of the “output measurement instrument” in the present disclosure.

The beam splitter BS is arranged on the optical path of the laser light between the pulse laser device 90 and the laser light concentrating optical system 54. The beam splitter BS is configured to transmit a part of the incident laser light and reflect another part thereof.

The laser energy sensor 79 is arranged at a position where it receives light having transmitted through or reflected by the beam splitter BS. Here, the laser energy sensor 79 exemplified in FIG. 16 is arranged at a position where it receives light having transmitted through the beam splitter BS. An optical system (not shown) may be arranged between the beam splitter BS and the laser energy sensor 79. The optical system may be a collimating optical system or a light concentrating optical system. The laser energy sensor 79 measures the laser energy laser, and transmits it to the EUV light generation processor 24. Other configurations may be similar to those of the EUV light generation apparatus 10. The laser energy sensor 79 is an example of the “laser light detection sensor” in the present disclosure.

### 3.2 Operation

The operation of the EUV light generation apparatus 10A will be described in terms of differences from the EUV light generation apparatus 10. During EUV light generation, the EUV light generation apparatus 10A controls the Duty of the piezoelectric element 47 using an EUV performance evaluation value such as the CE as a control amount.

The EUV light generation processor 24 measures, during EUV light generation, the CE based on the EUV energy measured by the energy sensor 78 and the laser energy measured by the laser energy sensor 79. Each of the EUV energy and the laser energy is an example of the “physical quantity” in the present disclosure.

Since the expression for the CE is Expression 2 described above, the CE may be calculated by measuring only the EUV energy at the time of CE measurement with the driver laser energy set to a known constant value. In this case, the EUV light generation apparatus 10A may not include the laser energy sensor 79 and the beam splitter BS. Further, in this case, the value of the EUV energy may be used instead of the CE. For example, in the descriptions with reference to FIGS. 13 and 14, the deterioration rate may be calculated using the value of the EUV energy instead of the CE, and may be used as a parameter related to the EUV light. That is, when the driver laser energy is treated as a known constant value, the CE measurement value, the CE difference, the frequency distribution of the CE difference, and the CE deterioration rate can be replaced with an EUV energy measurement value, an EUV energy difference, a frequency distribution of the EUV energy difference, and an EUV energy deterioration rate, respectively.

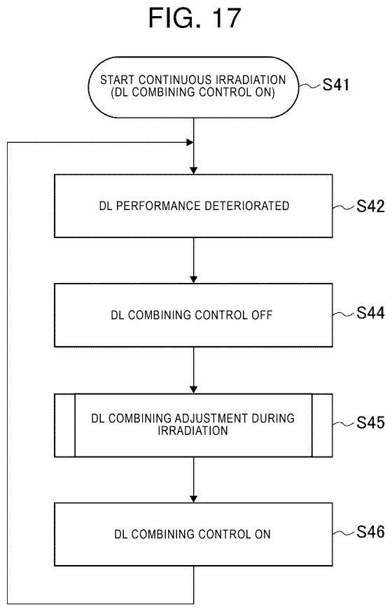

FIG. 17 is a flowchart showing the operation when the DL combining performance is deteriorated during the continuous irradiation of the EUV light generation apparatus 10A according to the first embodiment. The EUV light generation apparatus 10A operates in accordance with the flowchart of FIG. 17 instead of the flowchart of FIG. 15.

In step S41, the EUV light generation processor 24 starts continuous irradiation of the DL with the laser light. Step S41 can be started by starting the DL combining control shown in step S4 in FIG. 5.

The DL combining control is a process of finely adjusting the Duty (%) using the DL passage interval σ (ns) and the CE deterioration rate (%) as indices or using only the DL passage interval σ (ns) as an index. That is, the DL combining control is understood as a local search process of searching the optimum Duty near the Duty value set through the DL combining adjustment (step S3 in FIG. 5).

Thereafter, there may be a case that the DL performance deteriorates during the continuous irradiation, and that setting an appropriate Duty in the local search of the DL combining control (step S42) becomes difficult. That is, in step S42, when deterioration occurs in the DL combining performance which cannot be dealt with the DL combining control, the EUV light generation processor 24 proceeds to step S44 and stops the DL combining control. However, the continuous irradiation with the laser light is continued. The DL combining performance is an example of the “droplet generation performance” in the present disclosure.

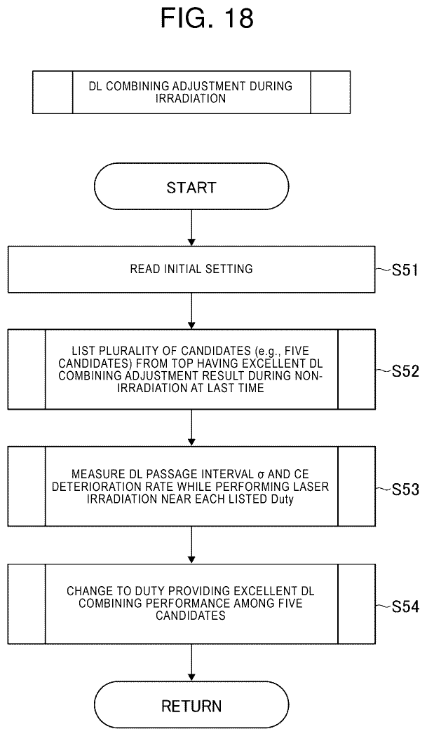

Then, in step S45, the EUV light generation processor 24 performs the DL combining adjustment during irradiation. The DL combining control during irradiation is a process of searching the Duty over a wide range while avoiding generation of debris using the DL passage interval σ (ns) and the CE deterioration rate (%) as indices. When the DL combining adjustment is performed during irradiation, some EUV performance deterioration is tolerated. Details of the DL combining adjustment during irradiation will be described later with reference to FIG. 18.

After the piezoelectric Duty is set through the DL combining adjustment during irradiation, processing proceeds to step S46. In step S46, the EUV light generation processor 24 starts the DL combining control. By restarting the DL combining control in step S46, fine adjustment of the Duty (%) is performed using the DL passage interval σ (ns) and the CE deterioration rate (%) as indices or using only the DL passage interval σ [ns] as an index. After step S46, the operation of the EUV light generation apparatus 10 returns to step S42.

According to the flowchart of FIG. 17, the continuous irradiation may not be stopped through step S41 to step S42 and step S44 to step S46. Further, the DL combining adjustment (step S45) during irradiation can be performed during both continuous operation and recovery.

FIG. 18 is a flowchart showing an example of a subroutine of the DL combining control during irradiation applied to step S45 in FIG. 17.

In step S51, the EUV light generation processor 24 reads initial settings. As a parameter for performing the initial setting, for example, a Duty change amount d1 as a Duty search range may be 0.02(%), the number of samples of the index for evaluating the DL combining performance may be 20000, a search threshold Sd1 of the DL passage interval σ may be 300 (ns), and a search threshold Sc1 of the CE deterioration rate may be 1(%). The search threshold Sd1 is an example of the “second threshold” in the present disclosure, and the search threshold Sc1 is an example of the “third threshold” in the present disclosure.

In step S52, the EUV light generation processor 24 lists, for example, top five candidates among the Duties each having excellent DL combining performance from the result of the DL combining adjustment (step S3) performed during the non-irradiation.

For this purpose, the EUV light generation processor 24 stores in advance the Duty value which provides the minimum moving average value of the DL passage intervals σ calculated for each Duty region candidate in FIG. 7. Then, the EUV light generation processor 24 selects the top five candidates of the Duty values each providing the minimum moving average value from the stored data. The top five candidates may be selected while excluding candidates whose DL combining performance has deteriorated. Further, the number “5” of candidates of the five candidates is an example, and may be another number. The respective Duty values of the plurality of candidates listed in step S52 are selected from the Duties in different Duty regions. The top five candidates are examples of the “duty region candidates” in the present disclosure.

As described with reference to FIG. 7, the “different Duty region” refers to each of the plurality of Duty region candidates satisfying the condition that the DL passage interval σ is less than the threshold S₁ and the width of the consecutive region is equal to or more than the threshold B of the consecutive Duty width determination. In the example of FIG. 7, each of the four region candidates CA11, CA12, CA13, CA14 corresponds to the “different Duty region”. Being less than the threshold S₁ is an example of being “less than a first threshold” in the present disclosure. Being the equal to or more than the threshold B of the consecutive Duty width determination is an example of being “equal to or more than a seventh threshold” in the present disclosure.

In FIG. 7, four Duty regions satisfying a predetermined condition are provided, and one Duty region to which the currently set Duty value (current value) belongs is the region in which the DL combining performance is deteriorated so as not to be able to dealt with the DL combining control, so that the Duty value providing the minimum moving average value is selected from each of the remaining three Duty regions excluding the deteriorated region, and the top three candidates are listed. As described above, even in configuration selecting the top five candidates, if the number of Duty regions satisfying the condition is less than five, candidates for the number of Duty regions satisfying the condition are selected. This configuration is an example of “selecting and listing a plurality of duty values having relatively small minimum moving average values from the top” in the present disclosure.

In step S53, the EUV light generation processor 24 measures, as an index of the Duty combining performance, the DL passage interval σ and the CE deterioration rate while performing laser irradiation near each listed Duty. Specifically, the EUV light generation processor 24 first searches in the negative direction of the Duty starting from the Duty at a certain listed point, and then searches in the positive direction thereof. The end condition for the search is that either the DL passage interval σ or the CE deterioration rate is equal to or more than a corresponding search threshold. The Duty at a certain listed point is an example of the “reference duty value” in the present disclosure. Being during the laser irradiation is an example of being “during laser irradiation” in the present disclosure.

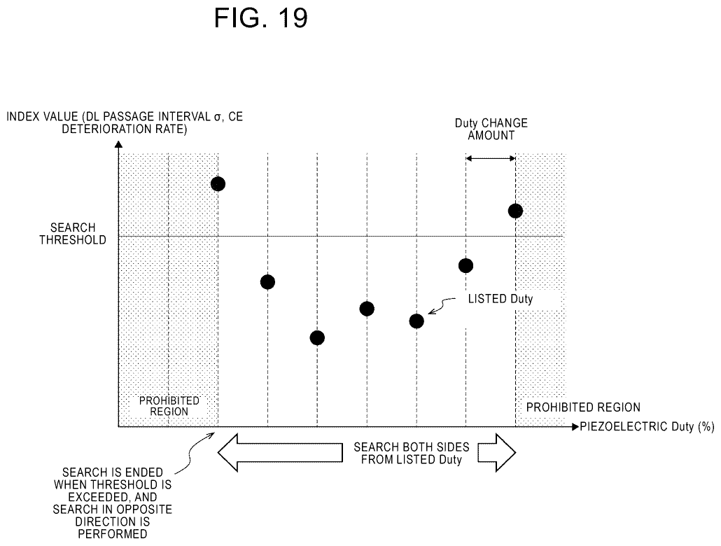

A specific example of the process of step S53 will be described with reference to FIG. 19. FIG. 19 is an example of a graph in which measurement values obtained by measuring the indices being the DL passage interval σ and the CE deterioration rate while performing laser irradiation near a certain Duty among the plurality of listed Duties are plotted. The horizontal axis represents the piezoelectric Duty (%), and the vertical axis represents the DL passage interval σ or the CE deterioration rate as an index value of the DL combining performance. The search threshold is the search threshold Sd1 or the search threshold Sc1.

The EUV light generation processor 24 measures the index value at each Duty value as changing the Duty from the listed Duty by the Duty change amount d1 in the negative direction. When the index value exceeds the search threshold, the search in the same direction is ended and the search in the opposite side (positive direction) is performed.

Similarly in the opposite side, the index value at each Duty value is measured as changing the Duty from the listed Duty by the Duty change amount d1 in the positive direction. When the index value exceeds the search threshold, the search in the same direction is ended. Here, the EUV light generation processor 24 may search either the negative side or the positive side first. The respective Duty values are examples of the “plurality of duty values” in the present disclosure.

In FIG. 19, the graph for only one index being the DL passage interval σ or the CE deterioration rate is shown, but the comparison with the corresponding search threshold is performed for each index of the DL passage interval σ and the CE deterioration rate. According to the process of step S53, near the listed Duty, the Duty region in which the DL passage interval σ is less than the search threshold Sd1 and the CE deterioration rate is less than the search threshold Sc1 is specified. Being less than the search threshold Sd1 is an example of being “less than a second threshold” in the present disclosure. Being less than the search threshold Sc1 is an example of being “less than a third threshold” in the present disclosure.

The Duty region satisfying the condition that the DL passage interval σ is less than the search threshold Sd1 and the CE deterioration rate is less than the search threshold Sc1, which is searched near each of the plurality of listed Duties, is referred to as the “first Duty candidate”. That is, the number of first Duty candidates is the same as the number of the plurality of listed Duty candidates at the maximum (for example, five candidates). The first Duty candidate is an example of the “first duty candidate” in the present disclosure.

In step S54 in FIG. 18, the EUV light generation processor 24 performs changing to the Duty providing the best DL combining performance among the five first Duty candidates. More specifically, for example, the EUV light generation processor 24 sets, as a “second Duty candidate”, a Duty region satisfying the condition that the DL passage interval σ and the CE deterioration rate are both less than the corresponding performance evaluation thresholds Sd2, Sc2 and the consecutive Duty region is equal to or more than a threshold C, among the five candidates (first Duty candidates), and performs changing to the Duty having the lowest moving-averaged passage interval σ among the second Duty candidate.

Here, the search threshold applied in step S53 and the performance evaluation threshold applied in step S54 may not be the same value or may be the same value.

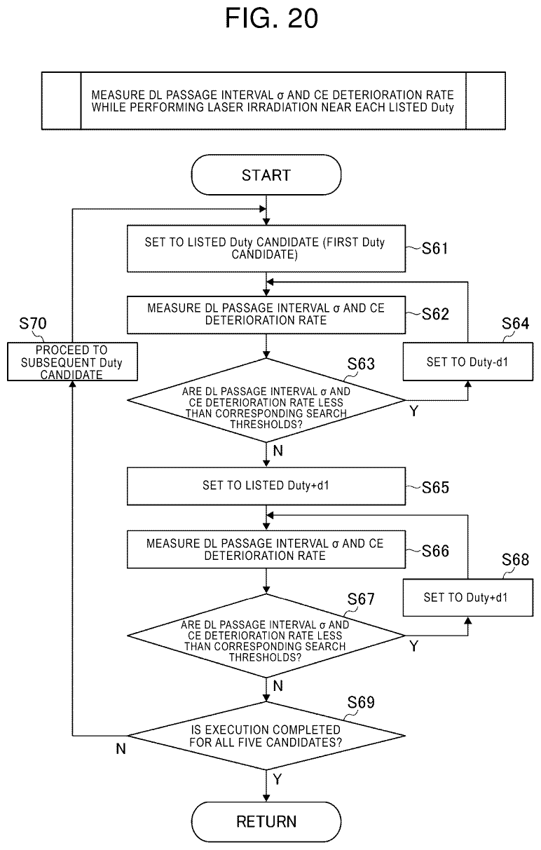

FIG. 20 is a flowchart showing an example of a process of a subroutine applied to step S53 in FIG. 18. The process of step S53 is understood as a search process for determining the width of the Duty region of each of the candidates corresponding to the plurality of listed Duties.

In step S61, the EUV light generation processor 24 sets the Duty to one of the five listed Duty candidates. Here, the list including five candidates is exemplified, but the list may include at least one candidate.

In step S62, the EUV light generation processor 24 measures the DL passage interval σ and the CE deterioration rate. The EUV light generation processor 24 stores the DL passage interval σ and the CE deterioration rate obtained by the measurement in association with the Duty.

In step S63, the EUV light generation processor 24 determines whether or not the DL passage interval σ and the CE deterioration rate measured in step S62 are less than the corresponding search thresholds. When the determination result of step S63 is Yes, that is, when the measured DL passage interval σ and the CE deterioration rate are less than the corresponding search thresholds, processing proceeds to step S64.

In step S64, the EUV light generation processor 24 changes the Duty from the current setting value (current value) by “−d1” and sets “Duty−d1” as the Duty. The Duty change amount d1 representing a step width of the Duty may be, for example, 0.02%.

After Duty setting is changed in step S64, processing returns to step S62.

When the determination result of step S63 is No, that is, when either or both of the DL passage interval σ and the CE deterioration rate obtained by the measurement in step S62 are equal to or more than the corresponding search thresholds, processing proceeds to step S65.

In step S65, the EUV light generation processor 24 adds “+d1” to the Duty set in step S61, and sets the Duty to “Duty+d1”.

In step S66, the EUV light generation processor 24 measures the DL passage interval σ and the CE deterioration rate. The EUV light generation processor 24 stores the DL passage interval σ and the CE deterioration rate obtained by the measurement in association with the Duty.

In step S67, the EUV light generation processor 24 determines whether or not the DL passage interval σ and the CE deterioration rate measured in step S66 are less than the corresponding search thresholds. When the determination result of step S67 is Yes, that is, when the measured DL passage interval σ and the CE deterioration rate are less than the corresponding search thresholds, processing proceeds to step S68.

In step S68, the EUV light generation processor 24 changes the Duty from the current setting value (current value) by “+d1” and sets “Duty+d1” as the Duty. After Duty setting is changed in step S68, processing returns to step S66.

When the determination result of step S67 is No, that is, when either or both of the DL passage interval σ and the CE deterioration rate obtained by the measurement in step S66 are equal to or more than the corresponding search thresholds, processing proceeds to step S69.

In step S69, the EUV light generation processor 24 determines whether or not the execution of the search process for determining the width of the Duty region is completed for the all five candidates. When the determination result of step S69 is No, that is, when some of the listed Duty candidates still remains, processing proceeds to step S70.

In step S70, the EUV light generation processor 24 sets the target of the process to the subsequent Duty candidate, and returns to step S61.

When the determination result of step S69 is Yes, that is, when the execution of the search process is completed for the all five candidates, the EUV light generation processor 24 ends the flowchart of FIG. 20 and returns to the flowchart of FIG. 18.

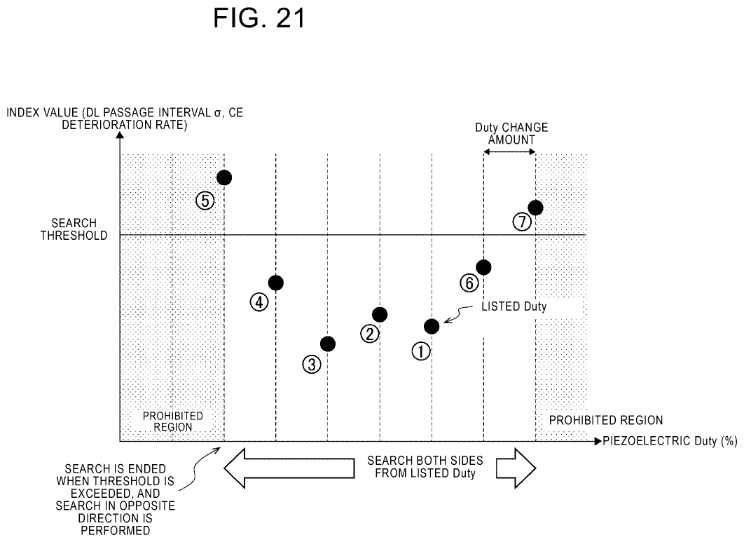

FIG. 21 shows a measurement order, in the graph of FIG. 19, of the index values measured in accordance with the flowchart of FIG. 20. The circled numbers indicate measurement orders of the index values. The Duty with number 1 in FIG. 21 is the listed Duty and corresponds to the Duty set in step S61. The Duties with numbers 2 to 4 are the Duties set in step S64, and the Duties with which the determination result of step S63 is Yes. The Duty with number 5 is the Duty which is set in step S64, and with which the determination result of step S63 is No.

The Duty with number 6 corresponds to the Duty set in step S66. The Duty with number 7 is the Duty which is set in step S68, and with which the determination result of step S67 is No.

In the case of searching the positive side from number 1 first, numbers 6 and 7 in FIG. 21 may be the numbers 2 and 3, respectively, and numbers 2 to 5 in FIG. 21 may be numbers 4 to 7, respectively.

Although one Duty candidate is shown in FIG. 21, searching is performed for the five Duty region candidates in total corresponding respectively to the plurality of the listed Duties. The Duty regions of the candidates respectively searched in this way are discretely distributed on the Duty axis without overlapping each other. The Duty regions of the respective candidates are an example of the “plurality of duty regions” in the present disclosure.

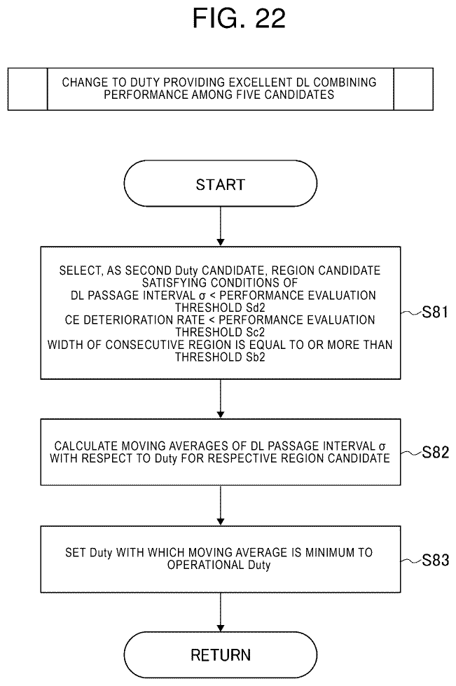

FIG. 22 is a flowchart showing an example of a process of a subroutine applied to step S54 in FIG. 18. The process of step S54 is understood as a process for setting the Duty having the smallest moving average of the DL passage intervals σ among the candidates satisfying a more stringent threshold condition, taking into account the width of the Duty region.

In step S81, the EUV light generation processor 24 selects the Duty region candidate satisfying the condition that “the DL passage interval σ is less than the performance evaluation threshold Sd2, the CE deterioration rate is less than the performance evaluation threshold Sc2, and the width of the consecutive Duty region is equal to or more than the threshold Sb2” from the search results of the five candidates. The EUV light generation processor 24 sets the Duty region candidate selected in step S81 as the second Duty candidate.

The performance evaluation threshold Sd2 for the DL passage interval σ may be, for example, 250 ns. Being less than the performance evaluation threshold Sd2 is an example of being “less than a fourth threshold” in the present disclosure.

The performance evaluation threshold Sc2 for the CE deterioration rate may be, for example, 0.01%. Being less than the performance evaluation threshold Sc2 is an example of being “less than a fifth threshold” in the present disclosure. The threshold Sb2 for determining the width of the consecutive region is referred to as the threshold of the consecutive Duty width determination. The threshold Sb2 of the consecutive Duty width determination may be, for example, 0.30%. Being equal to or more than the threshold Sb2 of the consecutive Duty width determination is an example of being “equal to or more than a sixth threshold value” in the present disclosure.

In step S82, the EUV light generation processor 24 calculates the moving averages of the DL passage interval σ with respect to the Duty for the respective Duty region candidates selected in step S81. The Duty region candidate selected in step S81 is an example of the “second duty candidate” in the present disclosure.

In step S83, the EUV light generation processor 24 sets the Duty with which the moving-averaged DL passage interval σ is the minimum to the operational Duty from the calculation result of step S82.

After step S83, the EUV light generation processor 24 ends the flowchart of FIG. 22 and returns to the flowchart of FIG. 18.

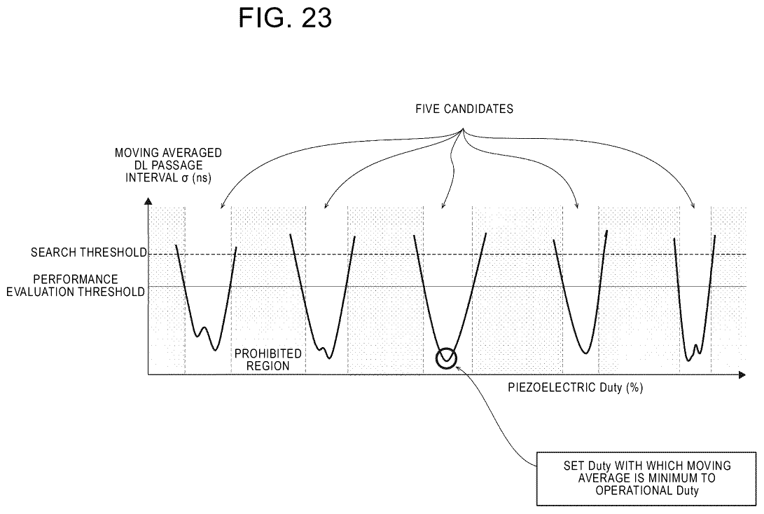

FIG. 23 is an explanatory diagram showing an example of selecting an optimum Duty from the five candidates. In FIG. 23, the horizontal axis represents the piezoelectric Duty (%), and the vertical axis represents the moving-averaged DL passage interval σ (ns). FIG. 23 shows graphs showing calculated moving averages of the DL passage intervals σ of the five Duty regions selected in step S81. Among the five region candidates shown in FIG. 23, the moving average of the DL passage intervals σ is minimized in the region candidate shown at the center.

### 3.2.1 Example of DL Combining Control Based on EUV Light

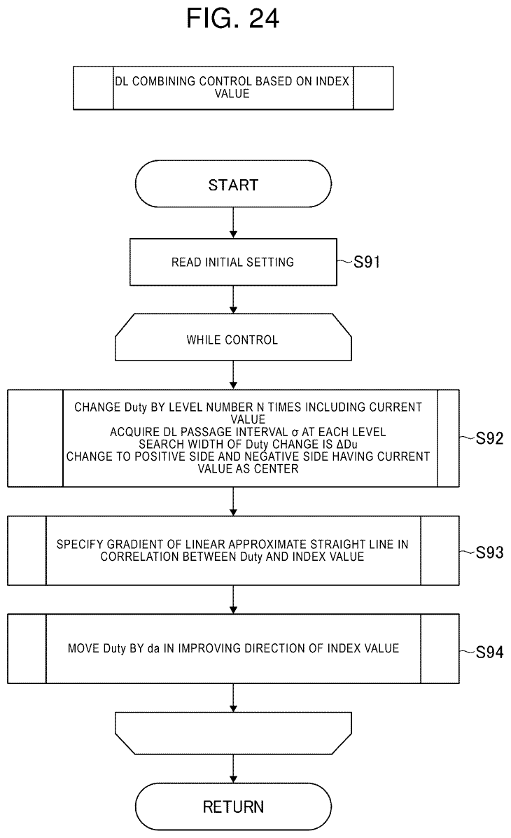

FIG. 24 is a flowchart showing an example of the subroutine of the DL combining control based on the EUV light. The DL combining control based on the EUV light shown in FIG. 24 is performed at the time of the EUV emission. The flowchart of FIG. 24 is applied to the DL combining control of step S4 in FIG. 5, and step S41 and step S46 in FIG. 17.

In step S91, the EUV light generation processor 24 reads initial settings. For example, as the parameters for performing the initial setting, the search range ΔDu may be 0.02(%), the search level number N may be 5, the Duty moving amount da may be 0.02(%), the number of index samples may be 20000, and a threshold E₁ of the index may be 0.05.

The processes of steps S92 to S94 are processes to be repeated. In step S92, the EUV light generation processor 24 changes the Duty on each of the positive side and the negative side having the current value of the Duty as the center, based on the read initial setting, and acquires the index values with the respective Duty values of N levels including the current value. In this case, the index value may be the DL passage interval σ or the CE deterioration rate. The interval between the N levels may be the search width ΔDu, and the order of the Duty to be set at the time of the level change is arbitrary. Here, the search level number N is equal to or more than 2, for example, 5. Further, it is desirable that the range of the search width Δdu is set to a width such that a significant difference is obtained in the index value.

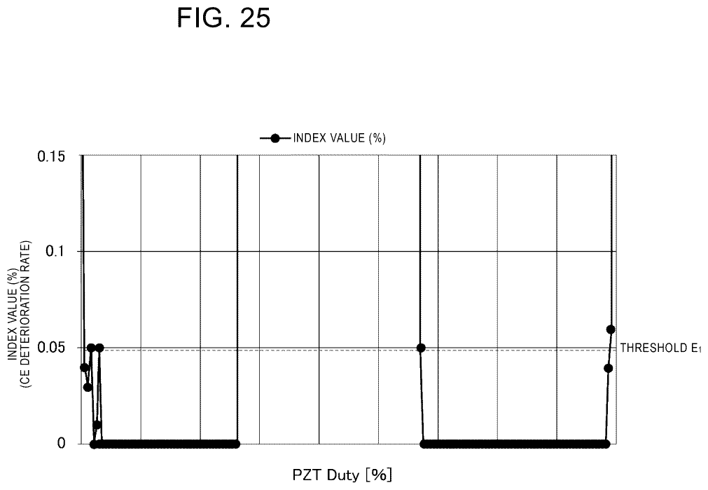

When the index value exceeds the threshold E₁, the EUV light generation processor 24 the stores current piezoelectric Duty (see FIG. 25). When the Duty after the change at the time of level change is a prohibited Duty (piezoelectric Duty with an index value equal to or more than E₁) or crosses the prohibited Duty, the EUV light generation processor 24 does not set the piezoelectric Duty to the positive side or the negative side.

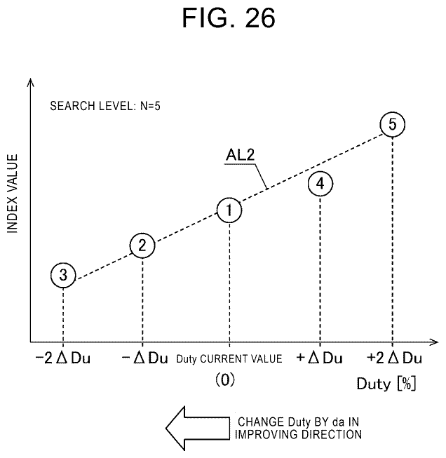

In step S93, the EUV light generation processor 24 calculates a linear approximate straight line in the correlation between the Duty acquired in step S92 and the index value, and specifies the gradient (see FIG. 26).

In step S94, the EUV light generation processor 24 changes the Duty in the improving direction of the index value (performance) based on the gradient of the linear approximate straight line created in step S93. For example, when the gradient is positive, the Duty is changed from the current value (0 position) in the negative direction. The change of the Duty at this time may be set with the moving amount da or set to any Duty in the improving direction. The change amount in the Duty may be varied depending on the value of the gradient.

After step S94, the EUV light generation processor 24 returns to step S92 and repeats the similar processing as having the changed Duty as the current value.

When the repetition termination conditions of steps S92 to S94 is satisfied, the EUV light generation processor 24 exits the flowchart of FIG. 24 and returns to the flowchart of FIG. 5 or FIG. 17.

FIG. 25 is a graph showing the relationship between the Duty acquired in step S93 and the index value. The horizontal axis represents the Duty, and the vertical axis represents the index value. Here, the index value may be the CE deterioration rate or the DL passage interval σ. When the index value is 0%, it indicates that the DL combining is in an excellent condition. As shown in FIG. 25, the Duty with which the index value exceeds the threshold E₁ is stored as the prohibited Duty that cannot be set.

FIG. 26 is a graph for explaining the process of changing the Duty in the improving direction of the index. In FIG. 26, the horizontal axis represents the Duty, and the vertical axis represents the index value. Each circle in FIG. 26 represents a plot position of the index value with respect to the Duty, and a number in the circle represents a search order. From these five plot points, an approximate straight line AL2 indicated by a broken line in FIG. 26 can be obtained by linear approximation.

In the example of FIG. 26, the gradient of the approximate straight line AL2 is positive, and the direction in which the Duty is decreased with respect to the current value is the direction in which the index value is improved. Therefore, in this case, as the process of step S94, the Duty value is changed from the current value to the negative direction by the moving amount da.

### 3.2.2 DL Performance Deterioration Determination Method During DL Combining Control

Here, description will be provided on an example of the DL performance deterioration determination method during the DL combining control. In the while-control of FIG. 24, the DL performance deterioration determination is performed. The DL performance deterioration determination is a process of determining necessity of shifting from the “DL combining control” to the “DL combining adjustment during irradiation”.

The determination condition of the DL performance deterioration determination may be, for example, a condition that when the index value (the DL passage interval σ or the CE deterioration rate) exceeds the performance deterioration detection threshold value (C, D) by a predetermined number of times (F) or more within a predetermined monitoring time (T) during the while-control of the DL combining control, processing exits the while-control to end the DL combining control, and proceeds to the “DL combining adjustment during irradiation”.

The setting values of the parameters (T, F, C, D) according to the determination condition may be, for example, the following values.
Monitoring time T: 5 minutes
Upper limit of number of times of exceeding threshold: 4 times
Performance deterioration detection threshold C of CE deterioration rate: 0.05%
Performance deterioration detection threshold D of DL passage interval σ: 300 ns

In reading the initial setting of step S91 shown in FIG. 24, the parameters related to the determination conditions are read.

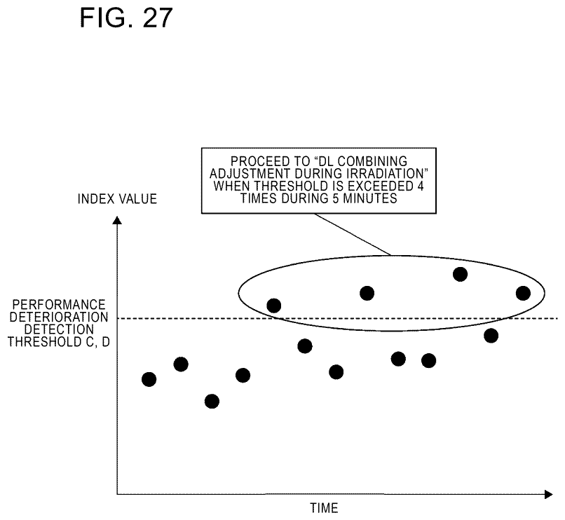

FIG. 27 is an example of a graph in which the index values obtained through the DL performance deterioration determination process during DL combining control are plotted. The horizontal axis represents time, and the vertical axis represents the index value. The index may be the CE deterioration rate or the DL passage interval σ.

When the index is the CE deterioration rate, the performance deterioration detection threshold is C, and when the index is the DL passage interval σ, the performance deterioration detection threshold is D. The performance deterioration detection threshold D is an example of the “droplet performance deterioration detection threshold” in the present disclosure.

When the index value exceeds the performance deterioration detection threshold C (or D) by four or more times, which is the upper limit F of the number of times exceeding the threshold, within a period of 5 minutes, which is the monitoring time T, as shown in the portion surrounded by an ellipse in FIG. 27, processing proceeds to the “DL combining adjustment during irradiation”. Exceeding four (the upper limit F of the number of times exceeding the threshold) or more times is an example of the “case of exceeding the specific number of times or more” in the present disclosure.

When the determination condition is satisfied in the determination result of the DL performance deterioration determination, it is assumed that the DL performance is deteriorated, and processing proceeds to step S44 in FIG. 17.

### 3.3 Effect

According to the EUV light generation apparatus 10A of the first embodiment, since searching the Duty over a wide range as having the CE deterioration rate as an index can be performed while suppressing generation of debris, the Duty can be set appropriately while avoiding a piezoelectric Duty band providing poor EUV performance.

### 4. Electronic Device Manufacturing Method

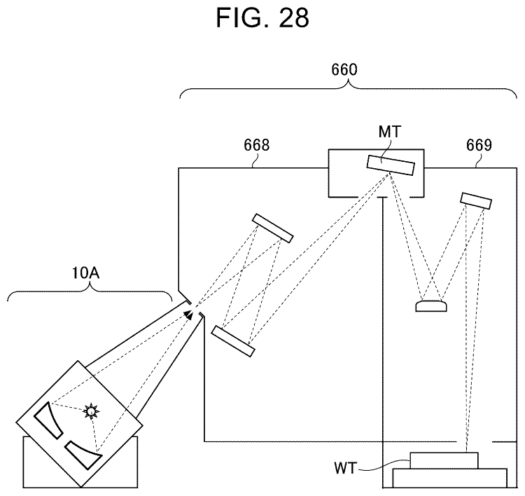

FIG. 28 is a diagram schematically showing the configuration of an exposure apparatus 660 connected to the EUV light generation apparatus 10A according to the first embodiment. In FIG. 28, the exposure apparatus 660 includes a mask irradiation unit 668 and a workpiece irradiation unit 669. The mask irradiation unit 668 illuminates, via a reflection optical system, a mask pattern of the mask table MT with the EUV light incident from the EUV light generation apparatus 10A. The workpiece irradiation unit 669 images the EUV light reflected by the mask table MT onto a workpiece (not shown) arranged on the workpiece table WT via a reflection optical system. The workpiece is a photosensitive substrate such as a semiconductor wafer on which photoresist is applied.

The exposure apparatus 660 synchronously translates the mask table MT and the workpiece table WT to expose the workpiece to the EUV light reflecting the mask pattern. Through the exposure process as described above, a device pattern is transferred onto the semiconductor wafer, thereby an electronic device can be manufactured.

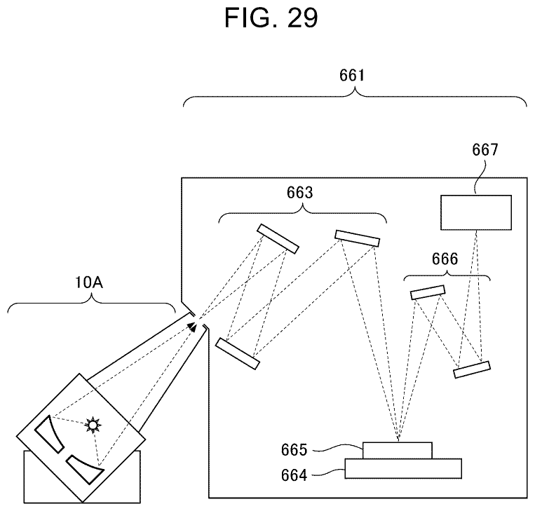

FIG. 29 is a diagram schematically showing the configuration of an inspection apparatus 661 connected to the EUV light generation apparatus 10A according to the first embodiment. The inspection apparatus 661 includes an illumination optical system 663 and a detection optical system 666. The illumination optical system 663 reflects the EUV light incident from the EUV light generation apparatus 10A to illuminate a mask 665 placed on a mask stage 664. Here, the mask 665 conceptually includes a mask blanks before a pattern is formed. The detection optical system 666 reflects the EUV light from the illuminated mask 665 and forms an image on a light receiving surface of a detector 667. The detector 667 having received the EUV light obtains the image of the mask 665. The detector 667 is, for example, a time delay integration (TDI) camera.

Inspection for a defect of the mask 665 is performed based on the image of the mask 665 obtained by the above-described detection steps, and a mask suitable for manufacturing an electronic device is selected using the inspection result. Then, the electronic device can be manufactured by exposing and transferring the pattern formed on the selected mask onto the photosensitive substrate using the exposure apparatus 660.

### 5. Processor

The processor such as the EUV light generation processor 24 may be physically configured as hardware to execute various processes included in the present disclosure. For example, the processor may be a computer including a memory that stores a control program defining the various processes and a processing device that executes the control program. The control program may be stored in one memory, or may be stored separately in a plurality of memories at physically separate locations, and the various processes included may be defined by the control program as an aggregation thereof. The processing device may be a general-purpose processing device such as a CPU or a special-purpose processing device such as a GPU.

Alternatively, the processor may be programmed as software to execute the various processes included in the present disclosure. For example, the processor may be implemented in a dedicated device such as an ASIC or a programmable device such as an FPGA.

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

### 6. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. An extreme ultraviolet light generation apparatus configured to generate extreme ultraviolet light by irradiating a target substance with laser light, comprising:
a nozzle configured to output the target substance;
a vibration element configured to be driven by an input of an electric signal of a rectangular wave and apply vibration to the target substance to be output from the nozzle to generate droplets of the target substance;
a timing sensor configured to detect a time interval variation of passage of the droplets output from the nozzle;
a processor configured to control a duty value of the electric signal for vibrating the vibration element; and
an output measurement instrument configured to measure a physical quantity for obtaining a parameter related to the generated extreme ultraviolet light,
the processor acquiring the time interval variation as changing the duty value while generating the droplets without generating the extreme ultraviolet light; selecting a plurality of duty values with which the time interval variation is less than a first threshold; acquiring the time interval variation and the parameter for each of the plurality of selected duty values as changing the duty value in a duty value region including the corresponding duty value while generating the extreme ultraviolet light to specify, as a first duty candidate, the duty value region in which the time interval variation is less than a second threshold and the parameter is less than a third threshold; and determining a duty value for vibrating the vibration element out of the first duty candidate.

2. The extreme ultraviolet light generation apparatus according to claim 1,
wherein the processor changes the duty value from a reference duty value in a negative direction and a positive direction while generating the extreme ultraviolet light as setting each of the plurality of duty values as the reference duty value for specifying the duty value region and acquires the time interval variation and the parameter with each of the duty values.

3. The extreme ultraviolet light generation apparatus according to claim 1,
wherein the first duty candidate includes a plurality of duty regions that are discretely present corresponding to the plurality of duty values.

4. The extreme ultraviolet light generation apparatus according to claim 1,
wherein the output measurement instrument includes an EUV light detection sensor configured to detect energy of the generated extreme ultraviolet light, and
the processor calculates an index indicating a variation of the energy of the generated extreme ultraviolet light as the parameter.

5. The extreme ultraviolet light generation apparatus according to claim 1,
wherein the output measurement instrument includes an EUV light detection sensor configured to detect energy of the generated extreme ultraviolet light, and a laser light detection sensor configured to detect energy of the laser light to be radiated to the target substance, and
the processor calculates an index indicating a variation of an energy conversion efficiency, which is a ratio of the energy of the extreme ultraviolet light to the energy of the laser light, as the parameter.

6. The extreme ultraviolet light generation apparatus according to claim 5,
wherein the variation of the energy conversion efficiency is evaluated using an index of any one of a standard deviation of the energy conversion efficiency, a standard deviation of difference in the energy conversion efficiency per pulse, and a deterioration rate of the energy conversion efficiency.

7. The extreme ultraviolet light generation apparatus according to claim 6,
wherein, when an integer representing a pulse number of the generated extreme ultraviolet light is k, and the energy conversion efficiency of the pulse number k is CE(k), the difference dCE(k) of the energy conversion efficiency is expressed by an expression of dCE(k)=CE(k)−CE(k−1).

8. The extreme ultraviolet light generation apparatus according to claim 7,
wherein the deterioration rate of the energy conversion efficiency is represented by a percentage of a value obtained by dividing a number of events in which the difference in the energy conversion efficiency is distributed outside an allowable range by a number of samples.

9. The extreme ultraviolet light generation apparatus according to claim 1,
wherein the processor specifies, as a second duty candidate out of the first duty candidate, a duty value region in which the time interval variation is less than a fourth threshold, the parameter is less than a fifth threshold, and a width of the duty value region is equal to or more than a sixth threshold; and determines, as a duty value for vibrating the vibration element, a duty value having a minimum moving average of the time interval variation with respect to the duty value out of the second duty candidate.

10. The extreme ultraviolet light generation apparatus according to claim 1,
wherein the processor selects a duty region candidate in which a width of a consecutive region of the duty value with which the time interval variation acquired without generating the extreme ultraviolet light is less than the first threshold is equal to or more than a seventh threshold; calculates a moving average of the time interval variation with respect to the duty value for each selected duty region candidate; and stores a duty value corresponding to a minimum moving average value of the time interval variation calculated for each duty region candidate.

11. The extreme ultraviolet light generation apparatus according to claim 10,
wherein the processor selects a plurality of duty values with which the time interval variation is less than the first threshold value out of the stored duty values corresponding to the minimum moving average values of the respective duty region candidates.

12. The extreme ultraviolet light generation apparatus according to claim 11,
wherein the processor selects a plurality of duty values each having a relatively small minimum moving average value out of the duty values corresponding to the minimum moving average values for the respective stored duty region candidates from the top and lists the selected duty values.

13. The extreme ultraviolet light generation apparatus according to claim 1,
wherein the processor acquires an index value based on the time interval variation or the parameter as changing the duty value while generating the extreme ultraviolet light; calculates an approximate straight line in a correlation between the duty value and the index value; and executes droplet combining control to change the duty value in a direction in which the index value improves based on a gradient of the approximate straight line.

14. The extreme ultraviolet light generation apparatus according to claim 13,
wherein the processor determines generation performance of the droplets by comparing the index value with a droplet performance deterioration detection threshold during execution of the droplet combining control; and when it is determined that the generation performance of the droplets is deteriorated, specifies the first duty candidate which is a duty region candidate different from the duty region candidate including a currently set duty value while generating the extreme ultraviolet light, and determines a duty value for vibrating the vibration element out of the first duty candidate.

15. The extreme ultraviolet light generation apparatus according to claim 14,
wherein the processor determines that the generation performance of the droplets is deteriorated when the index value exceeds the droplet performance deterioration detection threshold a predetermined number of times or more within a predetermined monitoring time during execution of the droplet combining control.

16. The extreme ultraviolet light generation apparatus according to claim 14,
wherein the processor shifts from the droplet combining control to droplet combining adjustment during laser irradiation when it is determined that the generation performance of the droplets is deteriorated; and in the droplet combining during laser irradiation, specifies the first duty candidate while generating the extreme ultraviolet light, and determines a duty value for vibrating the vibration element out of the first duty candidate.

17. The extreme ultraviolet light generation apparatus according to claim 16,
wherein the processor returns to the droplet combining control after executing the droplet combining adjustment during laser irradiation.

18. An electronic device manufacturing method, comprising:
generating extreme ultraviolet light using an extreme ultraviolet light generation apparatus;
outputting the extreme ultraviolet light to an exposure apparatus; and
exposing a photosensitive substrate to the extreme ultraviolet light in the exposure apparatus to manufacture an electronic device,
the extreme ultraviolet light generation apparatus including:
a nozzle configured to output a target substance;
a vibration element configured to be driven by an input of an electric signal of a rectangular wave and apply vibration to the target substance to be output from the nozzle to generate droplets of the target substance;
a timing sensor configured to detect a time interval variation of passage of the droplets output from the nozzle;
a processor configured to control a duty value of the electric signal for vibrating the vibration element; and
an output measurement instrument configured to measure a physical quantity for obtaining a parameter related to the extreme ultraviolet light generated by irradiating a target substance with laser light, and
the processor acquiring the time interval variation as changing the duty value while generating the droplets without generating the extreme ultraviolet light; selecting a plurality of duty values with which the time interval variation is less than a first threshold; acquiring the time interval variation and the parameter for each of the plurality of selected duty values as changing the duty value in a duty value region including the corresponding duty value while generating the extreme ultraviolet light to specify, as a first duty candidate, the duty value region in which the time interval variation is less than a second threshold and the parameter is less than a third threshold; and determining a duty value for vibrating the vibration element out of the first duty candidate.

19. An electronic device manufacturing method, comprising:
generating extreme ultraviolet light using an extreme ultraviolet light generation apparatus;
inspecting a defect of a mask by irradiating the mask with the extreme ultraviolet light;
selecting a mask using a result of the inspection; and
exposing and transferring a pattern formed on the selected mask onto a photosensitive substrate,
the extreme ultraviolet light generation apparatus including:
a nozzle configured to output a target substance;
a vibration element configured to be driven by an input of an electric signal of a rectangular wave and apply vibration to the target substance to be output from the nozzle to generate droplets of the target substance;
a timing sensor configured to detect a time interval variation of passage of the droplets output from the nozzle;
a processor configured to control a duty value of the electric signal for vibrating the vibration element; and
an output measurement instrument configured to measure a physical quantity for obtaining a parameter related to the extreme ultraviolet light generated by irradiating a target substance with laser light, and
the processor acquiring the time interval variation as changing the duty value while generating the droplets without generating the extreme ultraviolet light; selecting a plurality of duty values with which the time interval variation is less than a first threshold; acquiring the time interval variation and the parameter for each of the plurality of selected duty values as changing the duty value in a duty value region including the corresponding duty value while generating the extreme ultraviolet light to specify, as a first duty candidate, the duty value region in which the time interval variation is less than a second threshold and the parameter is less than a third threshold; and determining a duty value for vibrating the vibration element out of the first duty candidate.
